(19) United States
(12) Patent Application Publication
(10) Pub. No.: US 2026/0344010 A1
(43) Pub. Date: Oct. 29, 2026

(54) SELECTIVE GATE ELECTRODE LAYER DESPOSITION IN STACKING TRANSISTORS AND STRUCTURES RESULTING THEREFROM

(71) Applicant: Taiwan Semiconductor Manufacturing Co., Ltd., Hsinchu (TW)

(72) Inventors: Kai-Chieh Yang, New Taipei City (TW); Min-Chang Tsai, Tainan City (TW); Wei-Yen Woon, Hsinchu (TW); Szuya Liao, Zhubei (TW)

(21) Appl. No.: 19/731,586

(22) Filed: Jul. 6, 2026

Related U.S. Application Data
(63) Continuation of application No. 19/045,667, filed on Feb. 5, 2025.
(60) Provisional application No. 63/706,829, filed on Oct. 14, 2024.

(51) Int. Cl. H10D 84/01; H10D 84/85

(52) U.S. Cl. CPC H10D 84/0177; H10D 84/0167; H10D 84/017; H10D 84/851; H10D 84/856

(57) ABSTRACT

In an embodiment, a method includes forming a multi-layer stack over a semiconductor substrate, the multi-layer stack comprising alternating semiconductor nanostructures and dummy nanostructures; forming lower source/drain regions, wherein lower semiconductor nanostructures of the semiconductor nanostructures extend between the lower source/drain regions; forming upper source/drain regions over the lower source/drain regions, wherein upper semiconductor nanostructures of the semiconductor nanostructures extend between the upper source/drain regions; removing the dummy nanostructures to form first openings between the lower semiconductor nanostructures, and second openings between the upper semiconductor nanostructures; forming a first metal-containing layer around the upper semiconductor nanostructures and in the second openings; exposing surfaces of the first metal-containing layer to a first molecular inhibitor to form a first passivation layer on the surfaces of the first metal-containing layer; and forming a lower gate electrode around the lower semiconductor nanostructures and in the first openings.

### CROSS-REFERENCE TO RELATED APPLICATIONS

This application is a continuation of U.S. Patent Application No. 19/045,667 filed on Feb. 5, 2025, which application claims priority to U.S. Application No. 63/706,829, filed on Oct. 14, 2024, which applications are hereby incorporated herein by reference.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise that should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example schematic of a stacked transistor, such as a complementary field-effect transistor (CFET), in a three-dimensional view, in accordance with some embodiments.

FIGS. 2-24B are views of intermediate stages in the manufacturing of CFETs, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

According to various embodiments, a semiconductor device that includes CFETs may be formed. A CFET includes a lower nanostructure-FET and an upper nanostructure-FET disposed over the lower nanostructure-FET. Forming the semiconductor device may include forming upper channel regions of upper nanostructure-FETs and lower channel regions of lower nanostructure-FETs, the upper channel regions and the lower channel regions being disposed over a fin. A gate dielectric layer is formed around the upper channel regions and the lower channel regions, and over the fin. A first metal-containing material layer may be formed around the upper channel regions, such that the gate dielectric layer is disposed between the first metal-containing material layer and the upper channel regions. The semiconductor device may be exposed to a first molecular inhibitor (e.g., an aniline or an aldehyde, or the like) such that the first molecular inhibitor selectively attaches to surfaces of the first metal-containing material layer around the upper channel regions. Lower gate electrodes are then formed over the gate dielectric layer and around the lower channel regions using a conformal deposition process such as atomic layer deposition (ALD), or the like, wherein during the deposition process, the first molecular inhibitor functions as a protective layer that prevents the formation of materials of the lower gate electrodes on surfaces of the first metal-containing material layer. After the formation of the lower gate electrodes, the first molecular inhibitor and the first metal-containing material layer are removed using suitable processes. The semiconductor device may then be exposed to a second molecular inhibitor (e.g., such as an aniline or aldehyde, or the like) such that the second molecular inhibitor selectively attaches to top surfaces of the lower gate electrodes. A second metal-containing material layer and a third metal-containing material layer may be formed sequentially around the upper channel regions, such that the gate dielectric layer is disposed between the second metal-containing material layer and the third metal-containing material layer, and the upper channel regions. During the formation of the second metal-containing material layer and the third metal-containing material layer, the second molecular inhibitor functions as a protective layer that prevents the formation of the second metal-containing material layer and the third metal-containing material layer on the top surfaces of the lower gate electrodes. After the formation of the second metal-containing material layer and the third metal- containing material layer, the second molecular inhibitor may be removed using a suitable process. Upper gate electrodes are then formed over the lower gate electrodes and around the gate dielectric layer, the second metal-containing material layer, the third metal-containing material layer, and the upper channel regions using a conformal deposition process such as ALD, or the like.

Advantageous features of one or more embodiments disclosed herein may allow for the formation of the lower gate electrodes around the lower channel regions, and the upper gate electrodes around the upper channel regions, wherein the upper gate electrodes are disposed over the lower gate electrodes, without having to perform an etch-back process to remove top portions of the lower gate electrodes. As a result, loading effects associated with the etch-back process that may cause variations in feature dimensions of the lower gate electrodes can be avoided, leading to improved uniformity and consistency in the lower and upper gate electrode dimensions. This may lead to enhanced device performance and improved device yields. In addition, the use of atomic layer deposition (ALD) for forming both the lower gate electrodes and the upper gate electrodes allows for conformal deposition of materials of the lower gate electrodes and the upper gate electrodes around the lower channel regions and the upper channel regions of the nanostructure-FETs, respectively. As a result, precise dimensional control of the lower gate electrodes and the upper gate electrodes can be achieved, which may allow for consistent device performance.

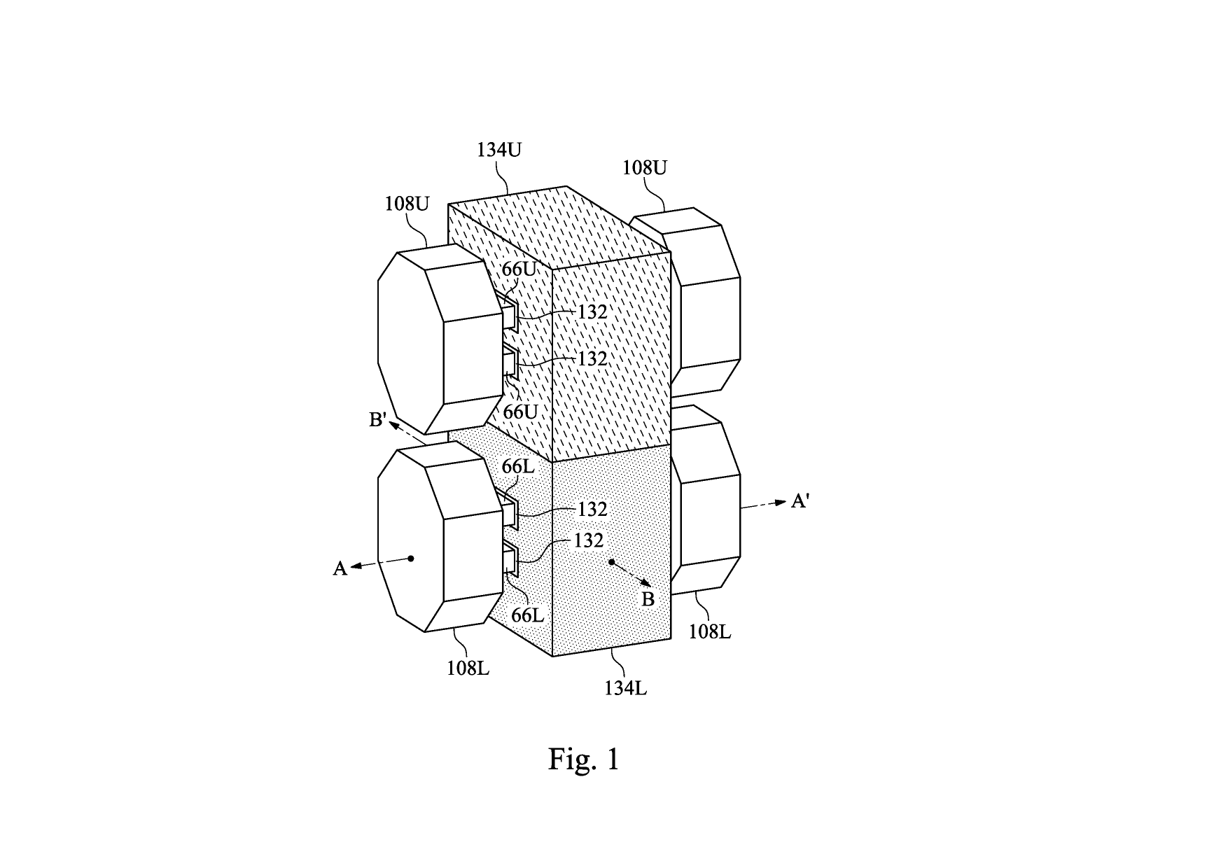

FIG. 1 illustrates an example schematic of a stacked transistor, such as a complementary field-effect transistor (CFET), in accordance with some embodiments. FIG. 1 is a three-dimensional view, where some features of the CFETs are omitted for illustration clarity.

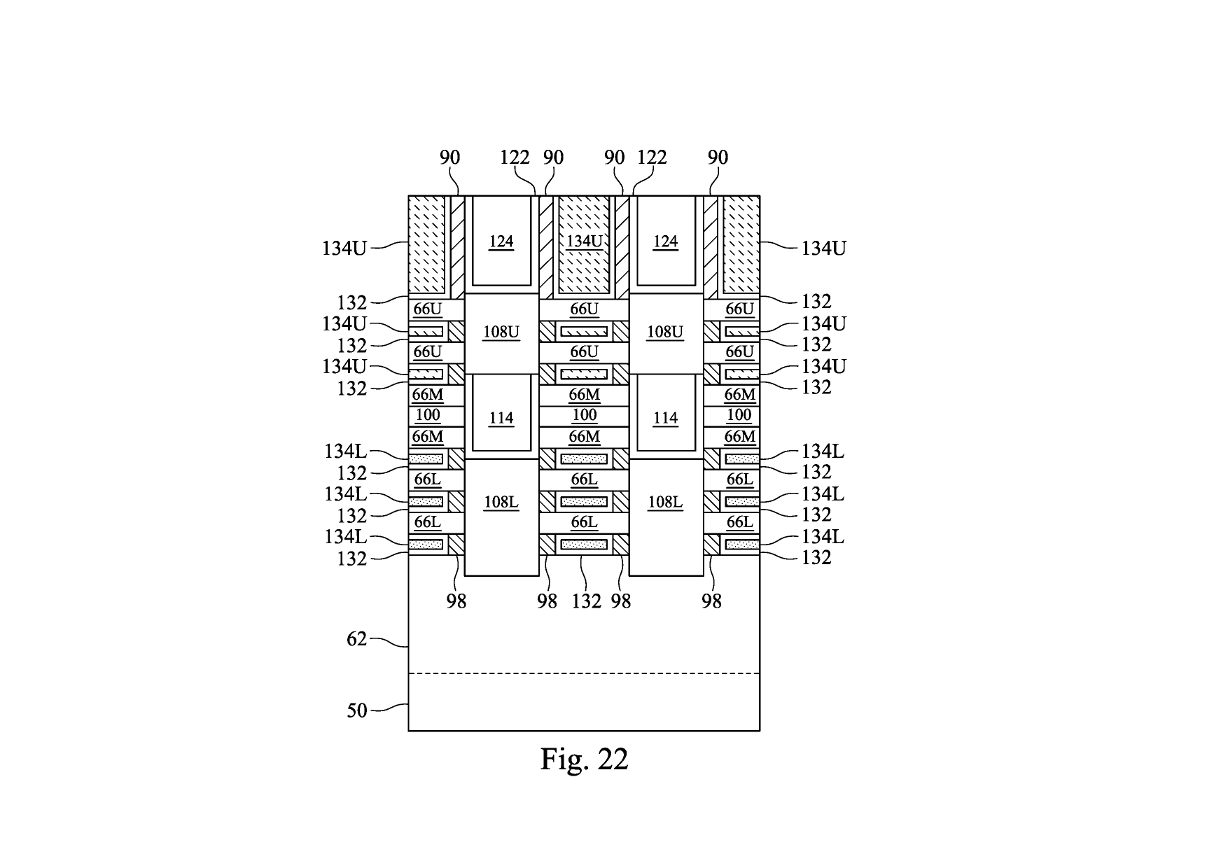

The CFETs include multiple vertically stacked nanostructure-FETs (e.g., nanowire FETs, nanosheet FETs, multi bridge channel (MBC) FETs, nanoribbon FETs, gate-all-around (GAA) FETs, or the like). For example, a CFET may include a lower nanostructure-FET of a first device type (e.g., n-type/p-type) and an upper nanostructure-FET of a second device type (e.g., p-type/n-type) that is opposite the first device type. Specifically, the CFET may include a lower PMOS transistor and an upper NMOS transistor, or the CFET may include a lower NMOS transistor and an upper PMOS transistor. Each of the nanostructure-FETs include semiconductor nanostructures 66 (including lower semiconductor nanostructures 66L and upper semiconductor nanostructures 66U), where the semiconductor nanostructures 66 act as channel regions for the nanostructure-FETs. The semiconductor nanostructures 66 may be nanosheets, nanowires, or the like. The lower semiconductor nanostructures 66L are for a lower nanostructure-FET and the upper semiconductor nanostructures 66U are for an upper nanostructure-FET. A channel isolation material (not explicitly illustrated in FIG. 1, see FIG. 22) may be used to separate and electrically isolate the upper semiconductor nanostructures 66U from the lower semiconductor nanostructures 66L.

Gate dielectrics 132 are along top surfaces, sidewalls, and bottom surfaces of the semiconductor nanostructures 66. Gate electrodes 134 (including a lower gate electrode 134L and an upper gate electrode 134U) are over the gate dielectrics 132 and around the semiconductor nanostructures 66. Source/drain regions 108 (including lower epitaxial source/drain regions 108L and upper epitaxial source/drain regions 108U) are disposed at opposing sides of the gate dielectrics 132 and the gate electrodes 134. Source/drain region(s) 108 may refer to a source or a drain, individually or collectively dependent upon the context. Isolation features may be formed to separate desired ones of the source/drain regions 108 and/or desired ones of the gate electrodes 134. For example, a lower gate electrode 134L may optionally be separated from an upper gate electrode 134U. Alternatively, a lower gate electrode 134L may be coupled to an upper gate electrode 134U. Further, the upper epitaxial source/drain regions 108U may be separated from lower epitaxial source/drain regions 108L by one or more dielectric layers (not explicitly illustrated in FIG. 1, see FIG. 22). The isolation features between channel regions, gates, and source/drain regions allow for vertically stacked transistors, thereby improving device density. Because of the vertically stacked nature of CFETs, the schematic may also be referred to as stacked transistors or folding transistors.

FIG. 1 further illustrates reference cross-sections that are used in later figures. Cross-section A-A' is parallel to a longitudinal axis of the semiconductor nanostructures 66 of a CFET and in a direction of, for example, a current flow between the source/drain regions 108 of the CFET. Cross-section B-B' is perpendicular to cross-section A-A' and along a longitudinal axis of a gate electrode 134 of a CFET. Subsequent figures refer to these reference cross-sections for clarity.

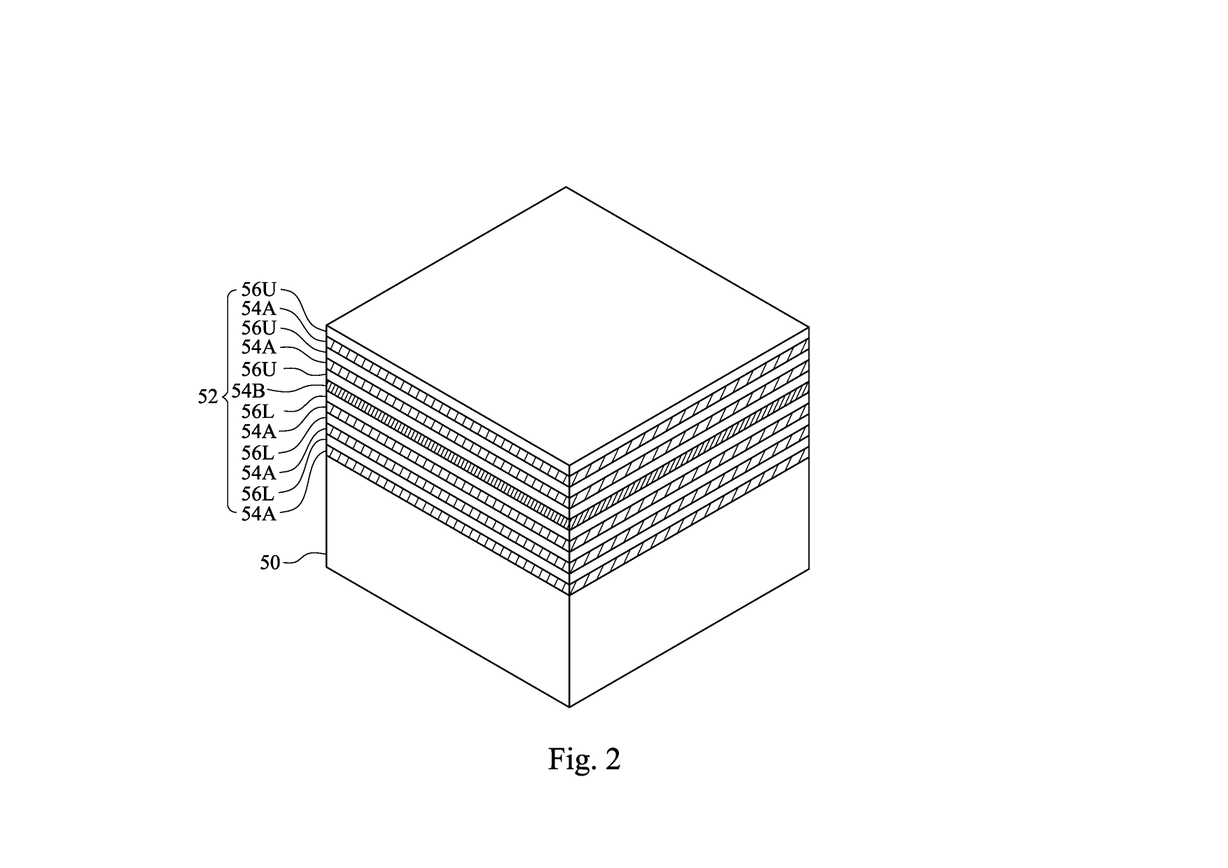

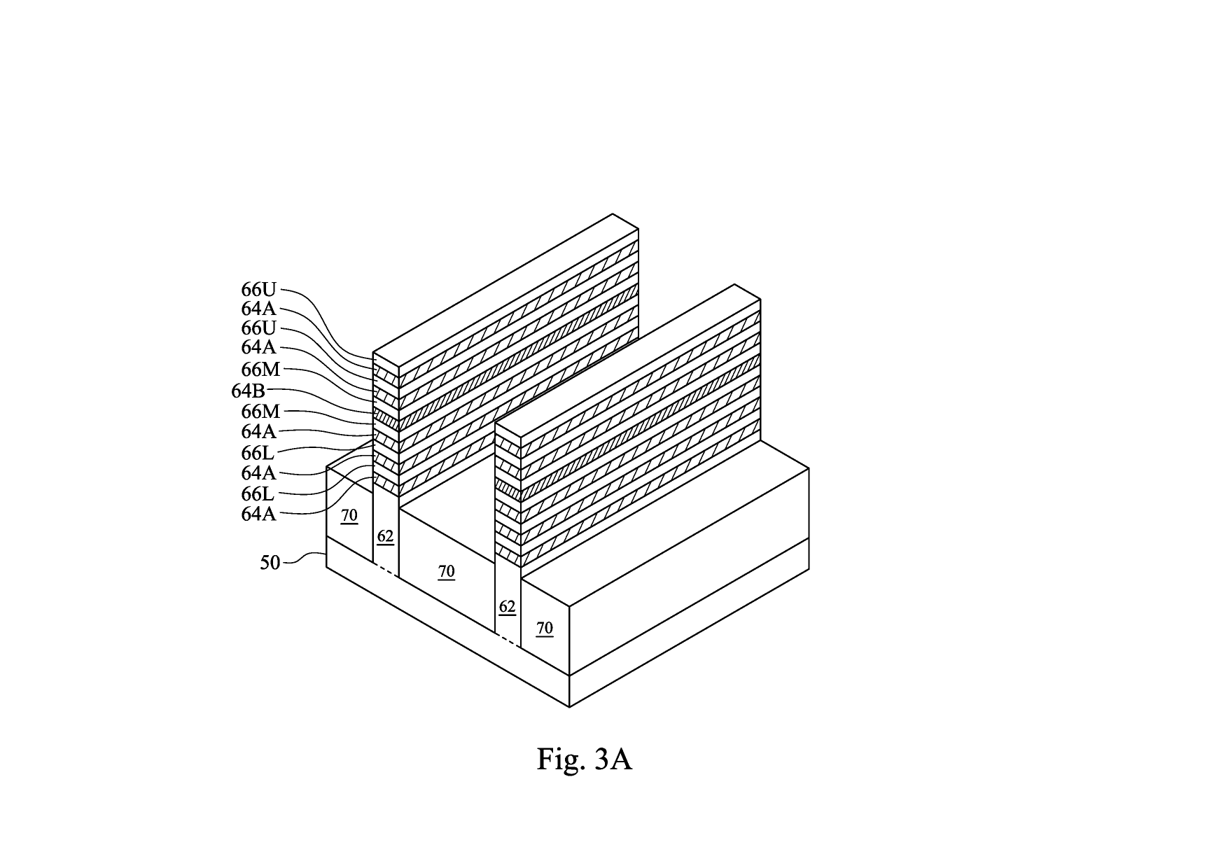

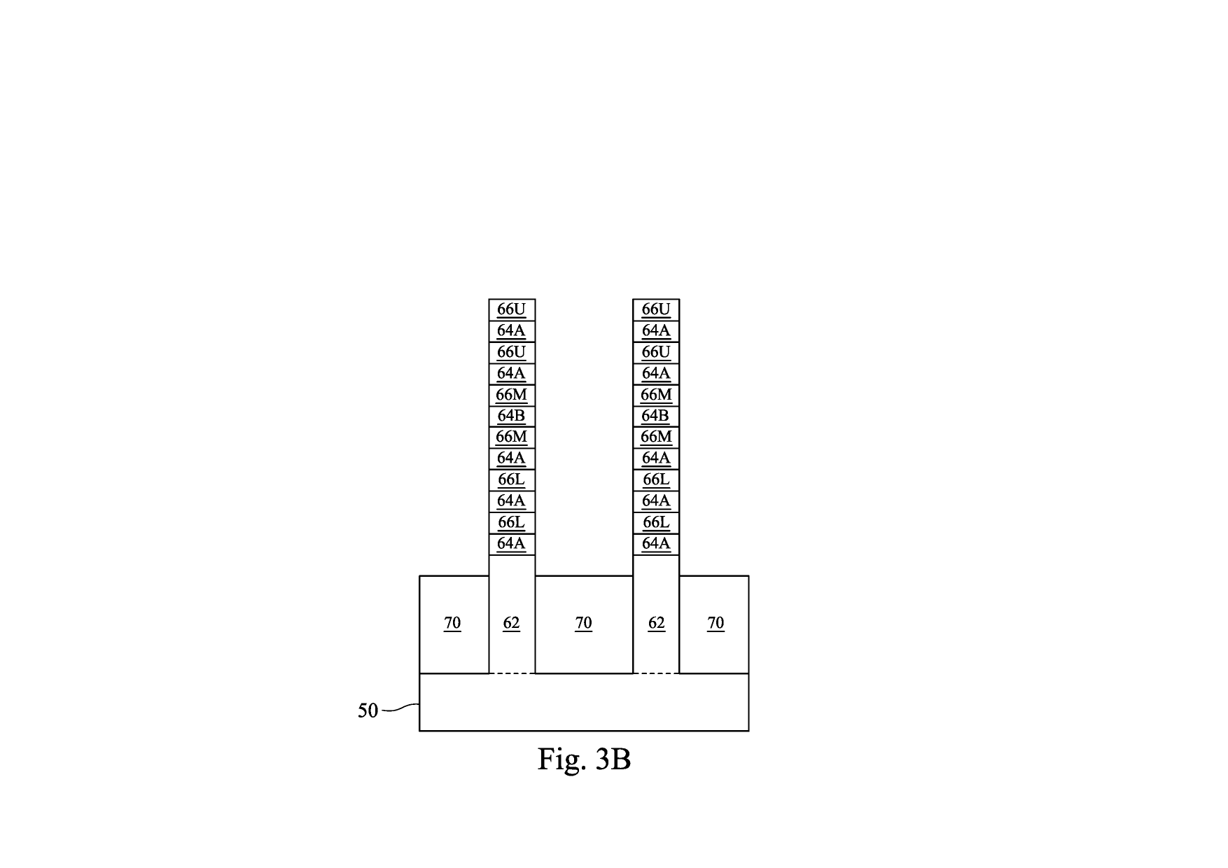

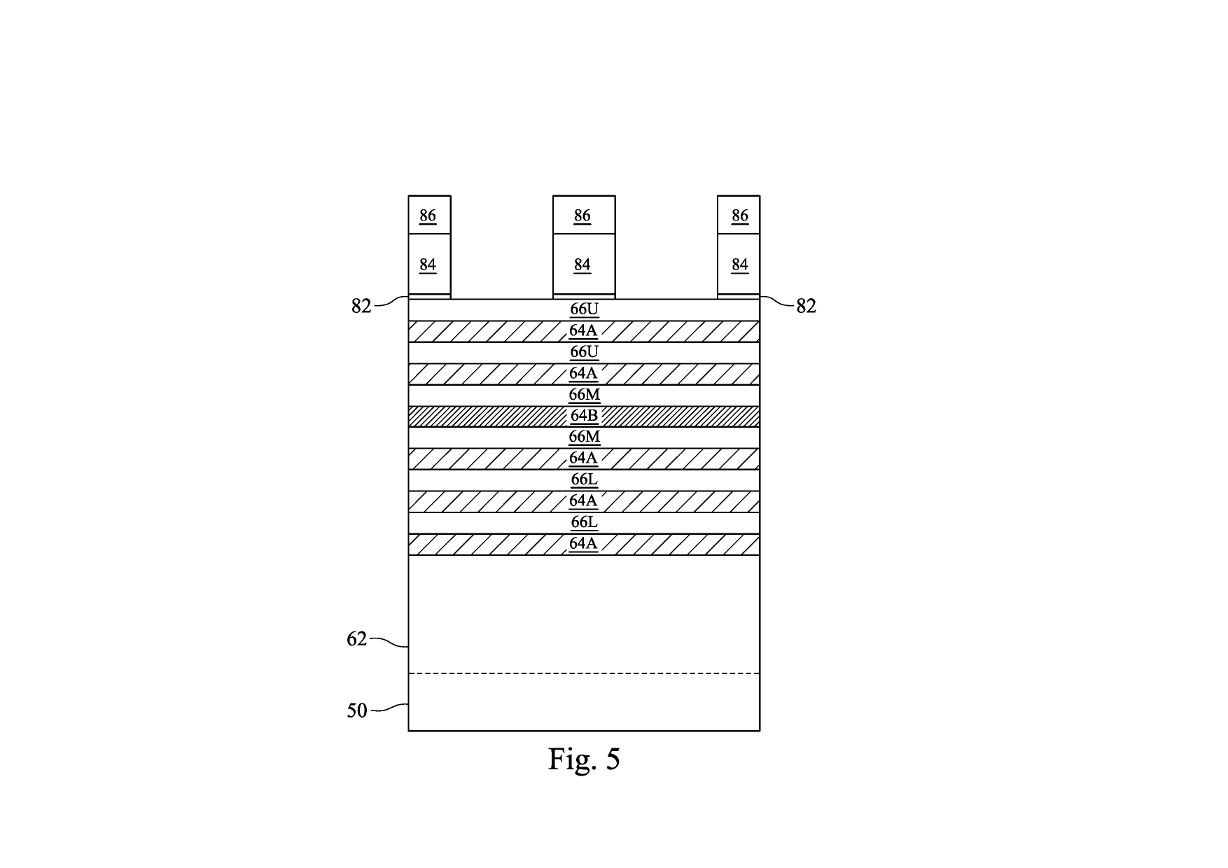

FIGS. 2-24B are views of intermediate stages in the manufacturing of CFETs, in accordance with some embodiments. FIGS. 2, 3A, and 4 are three-dimensional views showing a similar three-dimensional view as FIG. 1. FIGS. 5, 6, 7, 8, 9, 10A, 11A, 22, 23, and 24A illustrate cross-sectional views along a similar cross-section as reference cross-section A-A' in FIG. 1. FIGS. 3B, 10B, 11B, 12, 13, 14, 15, 16, 17, 18, 19, 20, 21, and 24B illustrate a cross-sectional view along a similar cross-section as reference cross-section B-B' in FIG. 1.

In FIG. 2, a substrate 50 is provided. The substrate 50 may be a semiconductor substrate, such as a bulk semiconductor, a semiconductor-on-insulator (SOI) substrate, or the like, which may be doped (e.g., with a p-type or an n-type dopant) or undoped. The substrate 50 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 50 may include silicon; germanium; a compound semiconductor including carbon-doped silicon, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof.

A multi-layer stack 52 is formed over the substrate 50. The multi-layer stack 52 includes alternating dummy layers 54 (including first dummy layers 54A and a second dummy layer 54B) and semiconductor layers 56 (including lower semiconductor layers 56L and upper semiconductor layers 56U). The lower semiconductor layers 56L and a subset of the first dummy layers 54A are disposed below the second dummy layer 54B. The upper semiconductor layers 56U and another subset of the first dummy layers 54A are disposed above the second dummy layer 54B. As subsequently described in greater detail, the dummy layers 54 will be removed and the semiconductor layers 56 will be patterned to form channel regions of CFETs. Specifically, the lower semiconductor layers 56L will be patterned to form channel regions of the lower nanostructure-FETs of the CFETs, and the upper semiconductor layers 56U will be patterned to form channel regions of the upper nanostructure-FETs of the CFETs.

The multi-layer stack 52 is illustrated as including a specific number of the dummy layers 54 and a specific number of the semiconductor layers 56. It should be appreciated that the multi-layer stack 52 may include any number of the dummy layers 54 and the semiconductor layers 56. Each layer of the multi-layer stack 52 may be grown by a process such as vapor phase epitaxy (VPE) or molecular beam epitaxy (MBE), deposited by a process such as chemical vapor deposition (CVD) or atomic layer deposition (ALD), or the like.

The first dummy layers 54A and the second dummy layer 54B may be formed of a first semiconductor material. The first semiconductor material may be selected from the candidate semiconductor materials of the substrate 50. In some embodiments, the dummy layers 54 (e.g., the first dummy layers 54A and the second dummy layer 54B) are formed of or comprise silicon germanium, and the second dummy layer 54B may be formed of germanium or silicon germanium with a higher germanium atomic percentage than the first dummy layers 54A. The first dummy layers 54A and the second dummy layer 54B have a high etching selectivity to one another, such that the second dummy layer 54B may be removed at a faster rate than the first dummy layers 54A in subsequent processing. The semiconductor layers 56 (including the lower semiconductor layers 56L and upper semiconductor layers 56U) are formed of a second semiconductor material that is different from the first semiconductor material. The second semiconductor material may be selected from the candidate semiconductor materials of the substrate 50. In some embodiments, the semiconductor layers 56 are formed of silicon. The semiconductor layers 56 and the dummy layers 54 have a high etching selectivity to one another, such that the dummy layers 54 (e.g., the first dummy layers 54A and the second dummy layer 54B) may be removed at a faster rate than the semiconductor layers 56 (e.g., the lower semiconductor layers 56L and the upper semiconductor layers 56U) in subsequent processing.

In FIGS. 3A and 3B, fins 62 are formed in the substrate 50 and nanostructures 64, 66 (including first dummy nanostructures 64A, second dummy nanostructures 64B, lower semiconductor nanostructures 66L, middle semiconductor nanostructures 66M, and upper semiconductor nanostructures 66U) are formed in the multi-layer stack 52. In some embodiments, the nanostructures 64, 66 and the fins 62 may be formed in the multi-layer stack 52 and the substrate 50, respectively, by etching trenches in the multi-layer stack 52 and the substrate 50. The etching may be any acceptable etch process, such as a reactive ion etch (RIE), neutral beam etch (NBE), the like, or a combination thereof. The etching may be anisotropic. Forming the nanostructures 64, 66 by etching the multi-layer stack 52 may define the first dummy nanostructures 64A from the first dummy layers 54A, the second dummy nanostructures 64B from the second dummy layer 54B, the lower semiconductor nanostructures 66L from some of the lower semiconductor layers 56L, the upper semiconductor nanostructures 66U from some of the upper semiconductor layers 56U, and the middle semiconductor nanostructures 66M from some of the lower semiconductor layers 56L and some of the upper semiconductor layers 56U. The first dummy nanostructures 64A and the second dummy nanostructures 64B may further be collectively referred to as the dummy nanostructures 64. The lower semiconductor nanostructures 66L and the upper semiconductor nanostructures 66U may further be collectively referred to as the semiconductor nanostructures 66.

As subsequently described in greater detail, various one of the nanostructures 64, 66 will be removed to form channel regions of CFETs. Specifically, the lower semiconductor nanostructures 66L will act as channel regions for lower nanostructure-FETs of the CFETs. Additionally, the upper semiconductor nanostructures 66U will act as channel regions for upper nanostructure-FETs of the CFETs.

The middle semiconductor nanostructures 66M are the semiconductor nanostructures 66 that are directly above/below (e.g., in contact with) the second dummy nanostructures 64B. Depending on the heights of subsequently formed source/drain regions, the middle semiconductor nanostructures 66M may or may not adjoin any source/drain regions and may or may not act as functional channel regions for the CFETs. The second dummy nanostructures 64B will be subsequently replaced with isolation structures. The isolation structures and the middle semiconductor nanostructures 66M may define boundaries of the lower nanostructure-FETs and the upper nanostructure-FETs.

The fins 62 and the nanostructures 64, 66 may be patterned by any suitable method. For example, the fins 62 and the nanostructures 64, 66 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins 62 and the nanostructures 64, 66. In some embodiments, a mask (or other layer) may remain on the nanostructures 64, 66.

Although each of the fins 62 and the nanostructures 64, 66 are illustrated as having a constant width throughout, in other embodiments, the fins 62 and/or the nanostructures 64, 66 may have tapered sidewalls such that a width of each of the fins 62 and/or the nanostructures 64, 66 continuously increases in a direction towards the substrate 50. In such embodiments, each of the nanostructures 64, 66 may have a different width and be trapezoidal in shape.

Further, isolation regions 70 are formed over the substrate 50 and between adjacent semiconductor fins 62. The isolation regions 70 may include a liner and a fill material over the liner. Each of the liner and the fill material may include a dielectric material such as an oxide (e.g., silicon oxide), a nitride (e.g., silicon nitride), the like, or a combination thereof. The formation of the isolation regions 70 may include depositing the dielectric material(s), and performing a planarization process such as a chemical mechanical polish (CMP) process, a mechanical polishing process, or the like to remove excess portions of the dielectric material(s), such as portions over the nanostructures 64, 66. The deposition processes may include ALD, high-density plasma chemical vapor deposition (HDP-CVD), flowable chemical vapor deposition (FCVD), the like, or a combination thereof. In some embodiments, the isolation regions 70 include silicon oxide formed by an FCVD process, followed by an anneal process. Then, the dielectric material(s) are recessed to define the isolation regions 70. The dielectric material(s) may be recessed such that upper portions of the semiconductor fins 62 and the nanostructures 64, 66 extend higher than the isolation regions 70.

The previously described process is just one example of how the fins 62 and the nanostructures 64, 66 may be formed. In some embodiments, the fins 62 and/or the nanostructures 64, 66 may be formed using a mask and an epitaxial growth process. For example, a dielectric layer can be formed over a top surface of the substrate 50, and trenches can be etched through the dielectric layer to expose the underlying substrate 50. Epitaxial structures can be epitaxially grown in the trenches, and the dielectric layer can be recessed such that the epitaxial structures protrude from the dielectric layer to form the fins 62 and/or the nanostructures 64, 66. The epitaxial structures may comprise the previously described alternating semiconductor materials, such as the first semiconductor material and the second semiconductor material. In some embodiments where epitaxial structures are epitaxially grown, the epitaxially grown materials may be in situ doped during growth, which may obviate prior and/or subsequent implantations, although in situ and implantation doping may be used together.

Further, appropriate wells (not separately illustrated) may be formed in the semiconductor nanostructures 66. In other embodiments, appropriate wells may be formed in the multi-layer stack 52 prior to the formation of the fins 62 and the nanostructures 64, 66. For example, an n-type impurity implant and/or a p-type impurity implant may be performed, or the semiconductor materials may be in situ doped during growth. The n-type impurities may be phosphorus, arsenic, antimony, or the like at a concentration in a range from 10¹⁷ atoms/cm³ to 10¹⁹ atoms/cm³. The p-type impurities may be boron, boron fluoride, indium, or the like at a concentration in a range from 10¹⁷ atoms/cm³ to 10¹⁹ atoms/cm³. The wells in the lower semiconductor nanostructures 66L have a conductivity type opposite from a conductivity type of lower source/drain regions that will be subsequently formed adjacent the lower semiconductor nanostructures 66L. The wells in the upper semiconductor nanostructures 66U have a conductivity type opposite from a conductivity type of upper source/drain regions that will be subsequently formed adjacent the upper semiconductor nanostructures 66U.

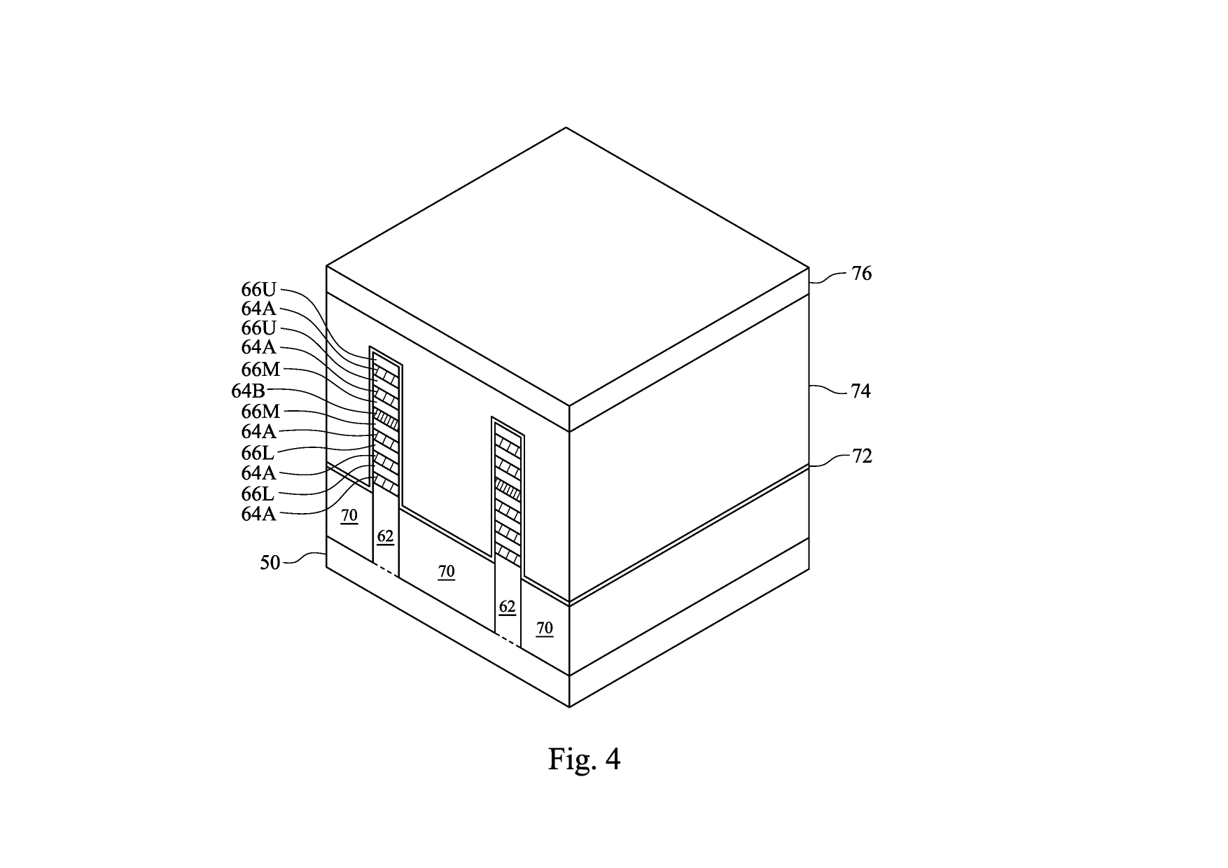

In FIG. 4, a dummy dielectric layer 72 is formed on the fins 62 and/or the nanostructures 64, 66. The dummy dielectric layer 72 may be, for example, silicon oxide, silicon nitride, a combination thereof, or the like, and may be deposited or thermally grown according to acceptable techniques. A dummy gate layer 74 is formed over the dummy dielectric layer 72, and a mask layer 76 is formed over the dummy gate layer 74. The dummy gate layer 74 may be deposited over the dummy dielectric layer 72 and then planarized, such as by a CMP. The mask layer 76 may be deposited over the dummy gate layer 74. The dummy gate layer 74 may be a conductive or non-conductive material and may be selected from a group including amorphous silicon, polycrystalline-silicon (polysilicon), poly-crystalline silicon-germanium (poly-SiGe), metallic nitrides, metallic silicides, metallic oxides, and metals. The dummy gate layer 74 may be deposited by physical vapor deposition (PVD), CVD, sputter deposition, or other techniques for depositing the selected material. The dummy gate layer 74 may be formed of other materials that have a high etching selectivity to insulating materials. The mask layer 76 may include, for example, silicon nitride, silicon oxynitride, or the like. In the illustrated embodiment, the dummy dielectric layer 72 covers the isolation regions 70, such that the dummy dielectric layer 72 extends between the dummy gate layer 74 and the isolation regions 70. In another embodiment, the dummy dielectric layer 72 covers only the fins 62 and/or the nanostructures 64, 66.

In FIG. 5, the mask layer 76 may be patterned using acceptable photolithography and etching techniques to form masks 86. The pattern of the masks 86 then may be transferred to the dummy gate layer 74 and to the dummy dielectric layer 72 to form dummy gates 84 and dummy dielectrics 82, respectively. The dummy gates 84 cover respective channel regions of the nanostructures 64, 66. The pattern of the masks 86 may be used to physically separate each of the dummy gates 84 from adjacent dummy gates 84. The dummy gates 84 may also have a lengthwise direction substantially perpendicular to the lengthwise direction of respective fins 62. The masks 86 can optionally be removed after patterning, such as by any acceptable etching technique.

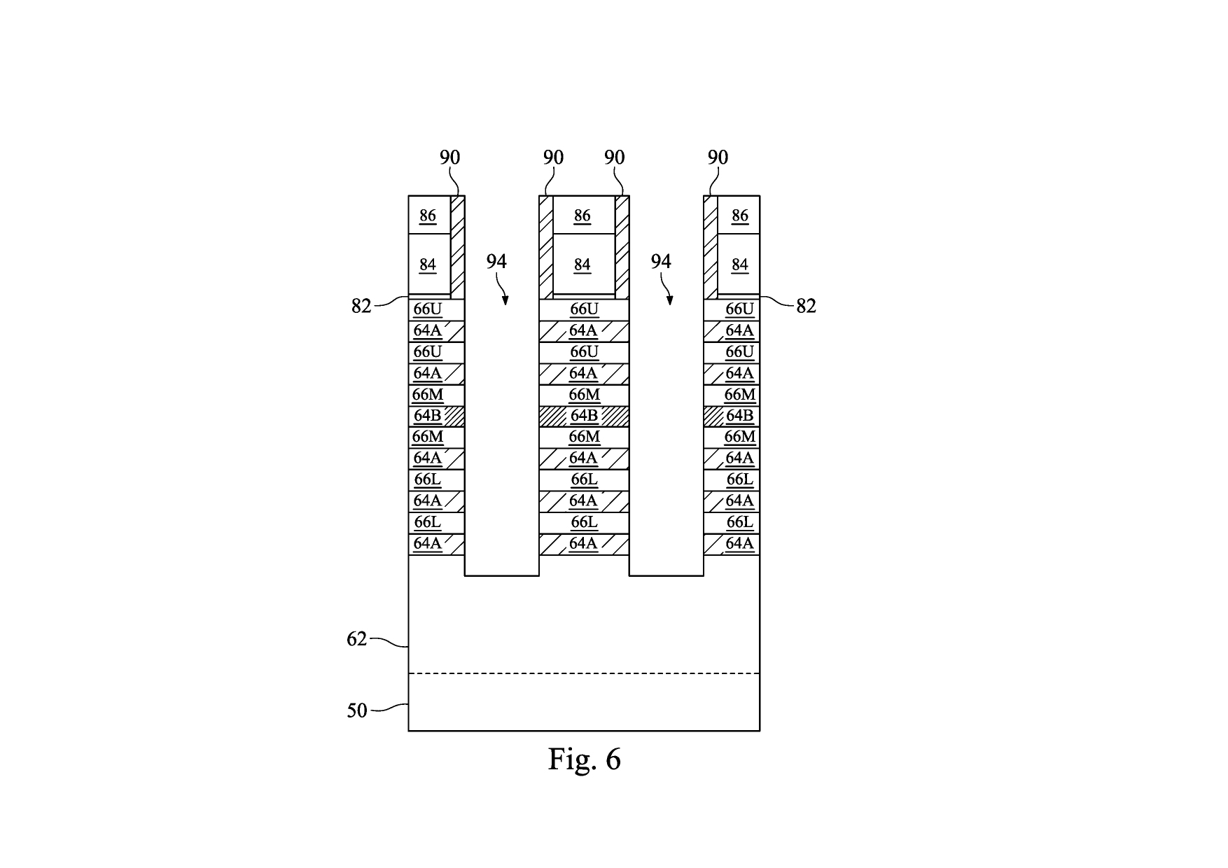

In FIG. 6, gate spacers 90 are formed over the nanostructures 64, 66 and on exposed sidewalls of the masks 86 (if present), the dummy gates 84, and the dummy dielectrics 82. The gate spacers 90 may be formed by conformally forming one or more dielectric material(s) and subsequently etching the dielectric material(s). Acceptable dielectric materials may include silicon oxide, silicon nitride, silicon oxynitride, silicon oxycarbonitride, or the like, which may be formed by a deposition process such as chemical vapor deposition (CVD), atomic layer deposition (ALD), or the like. Other dielectric materials formed by any acceptable process may be used. Any acceptable etch process, such as a dry etch, a wet etch, the like, or a combination thereof, may be performed to pattern the dielectric material(s). The etching may be anisotropic. The dielectric material(s), when etched, have portions left on the sidewalls of the dummy gates 84 (thus forming the gate spacers 90). In some embodiments, the dielectric material(s), when etched, may also have portions left on the sidewalls of the fins 62 and/or the nanostructures 64, 66.

Further, implants for lightly doped source/drain (LDD) regions (not separately illustrated) may be performed. The LDD implants may be performed before the gate spacers 90 are formed. Appropriate type impurities may be implanted into the nanostructures 64, 66 to a desired depth. The LDD regions may have a same conductivity type as a conductivity type of source/drain regions that will be subsequently formed adjacent the semiconductor nanostructures 66. Additionally, the LDD regions in the lower semiconductor nanostructures 66L may have a conductivity type opposite from a conductivity type of the LDD regions in the upper semiconductor nanostructures 66U. In some embodiments, the lower semiconductor nanostructures 66L have p-type LDD regions and the upper semiconductor nanostructures 66U have n-type LDD regions. In some embodiments, the lower semiconductor nanostructures 66L have n-type LDD regions and the upper semiconductor nanostructures 66U have p-type LDD regions. The n-type impurities may be the any of the n-type impurities previously discussed, and the p-type impurities may be the any of the p-type impurities previously discussed. The lightly doped source/drain regions may have a concentration of impurities in a range from 10¹⁷ atoms/cm³ to 10²⁰ atoms/cm³. An anneal may be used to repair implant damage and to activate the implanted impurities. In some embodiments, the grown materials of the nanostructures 64, 66 may be in situ doped during growth, which may obviate the implantations, although in situ and implantation doping may be used together.

It is noted that the previous disclosure generally describes a process of forming spacers and LDD regions. Other processes and sequences may be used. For example, fewer or additional spacers may be utilized, different sequence of steps may be utilized, additional spacers may be formed and removed, and/or the like.

Source/drain recesses 94 are formed in the fins 62, the nanostructures 64, 66, and the substrate 50. Epitaxial source/drain regions will be subsequently formed in the source/drain recesses 94. The source/drain recesses 94 may extend through the nanostructures 64, 66 and into the substrate 50. The fins 62 may be etched such that bottom surfaces of the source/drain recesses 94 are disposed above, below, or level with the top surfaces of the isolation regions 70. In the illustrated example, the top surfaces of the isolation regions 70 are above the bottom surfaces of the source/drain recesses 94. The source/drain recesses 94 may be formed by etching the fins 62, the nanostructures 64, 66, and the substrate 50 using anisotropic etching processes, such as RIE, NBE, or the like. The gate spacers 90 and the dummy gates 84 mask portions of the fins 62, the nanostructures 64, 66, and the substrate 50 during the etching processes used to form the source/drain recesses 94. A single etch process or multiple etch processes may be used to etch each layer of the nanostructures 64, 66 and/or the fins 62. Timed etch processes may be used to stop the etching of the source/drain recesses 94 after the source/drain recesses 94 reach a desired depth.

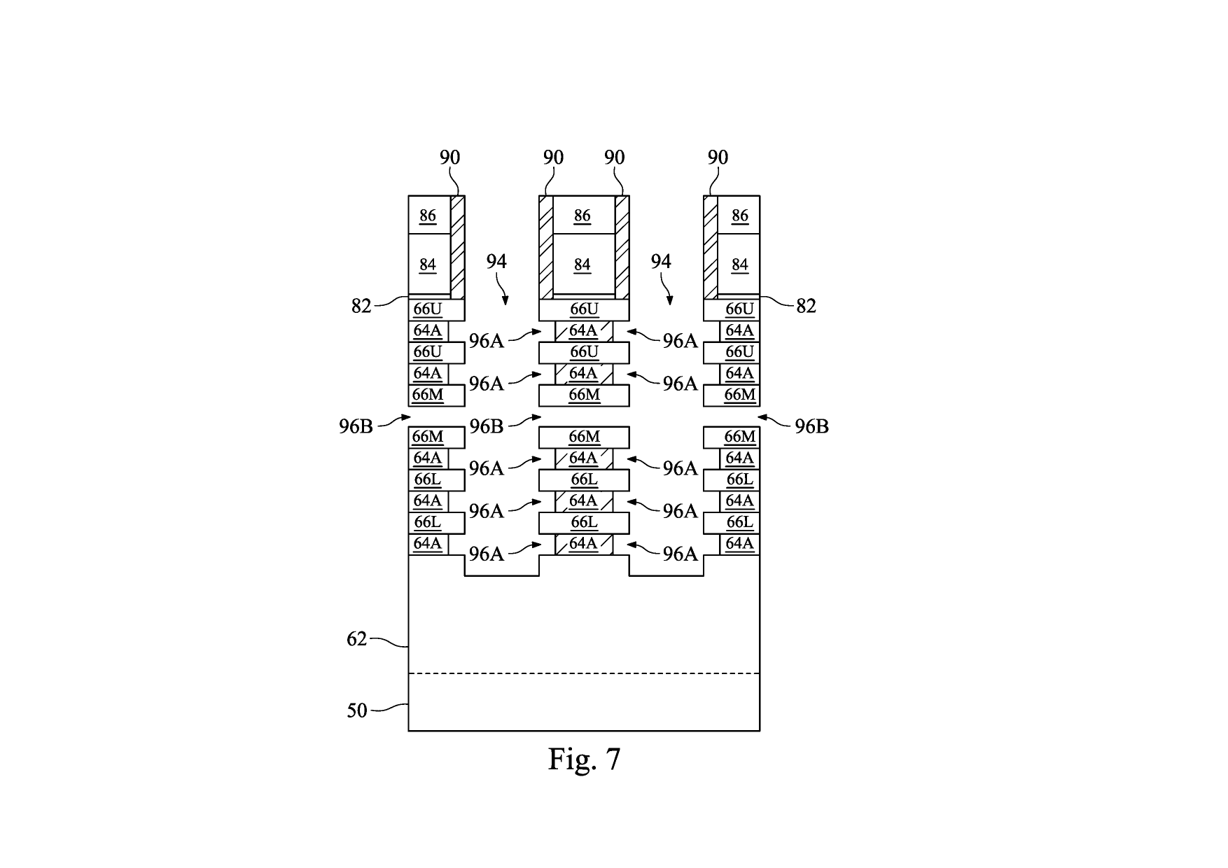

In FIG. 7, the sidewalls of the first dummy nanostructures 64A exposed by the source/drain recesses 94 are recessed to form sidewall recesses 96A. Additionally, the second dummy nanostructures 64B are removed to form openings 96B between the lower semiconductor nanostructures 66L (collectively) and the upper semiconductor nanostructures 66U (collectively). The sidewall recesses 96A will subsequently be filled with spacers. The openings 96B will subsequently be filled with isolation structures.

The sidewall recesses 96A may be formed by recessing the sidewalls of the first dummy nanostructures 64A with any acceptable etch process. The etching is selective to the first dummy nanostructures 64A (e.g., selectively etches the material of the first dummy nanostructures 64A at a faster rate than the material of the semiconductor nanostructures 66). The etching may be isotropic. Although sidewalls of the first dummy nanostructures 64A are illustrated as being straight after the etching, the sidewalls may be concave or convex.

The openings 96B may be formed by removing the second dummy nanostructures 64B with any acceptable etch process. The etching is selective to the second dummy nanostructures 64B (e.g., selectively etches the material of the second dummy nanostructures 64B at a faster rate than the material of the semiconductor nanostructures 66). The etching may be isotropic. The dummy gates 84 may adhere to and support the upper semiconductor nanostructures 66U so that the upper semiconductor nanostructures 66U do not collapse after the formation of the openings 96B.

In some embodiments, the same etching process is used to recess the sidewalls of the first dummy nanostructures 64A and to remove the second dummy nanostructures 64B. For example, the second dummy nanostructures 64B may be completely removed without completely removing the first dummy nanostructures 64A, and the first dummy nanostructures 64A may be recessed without significantly recessing the semiconductor nanostructures 66. The etching process has selectivity among the materials of the first dummy nanostructures 64A, the second dummy nanostructures 64B, and the semiconductor nanostructures 66. Specifically, the etching process selectively etches the material of the first dummy nanostructures 64A at a faster rate than the material of the semiconductor nanostructures 66, and also selectively etches the material of the second dummy nanostructures 64B at a faster rate than the material of the first dummy nanostructures 64A. Thus, the etch rate of the first dummy nanostructures 64A is less than the etch rate of the second dummy nanostructures 64B and is greater than the etch rate of the semiconductor nanostructures 66. In some embodiments where the second dummy nanostructures 64B are formed of germanium or silicon germanium with a high germanium atomic percentage, the first dummy nanostructures 64A are formed of silicon germanium with a low germanium atomic percentage, and the semiconductor nanostructures 66 are formed of silicon free from germanium, the etch process may comprise a dry etch process using chlorine gas, with or without a plasma.

The middle semiconductor nanostructures 66M are exposed by the openings 96B. In some embodiments, the etching process thins the middle semiconductor nanostructures 66M. Accordingly, the thickness of the middle semiconductor nanostructures 66M may be different (e.g., less than) the thickness of the lower semiconductor nanostructures 66L and the thickness of the upper semiconductor nanostructures 66U. In some embodiments, the middle semiconductor nanostructures 66M are from 0% to 20% thinner than the lower semiconductor nanostructures 66L and the upper semiconductor nanostructures 66U after the etching process.

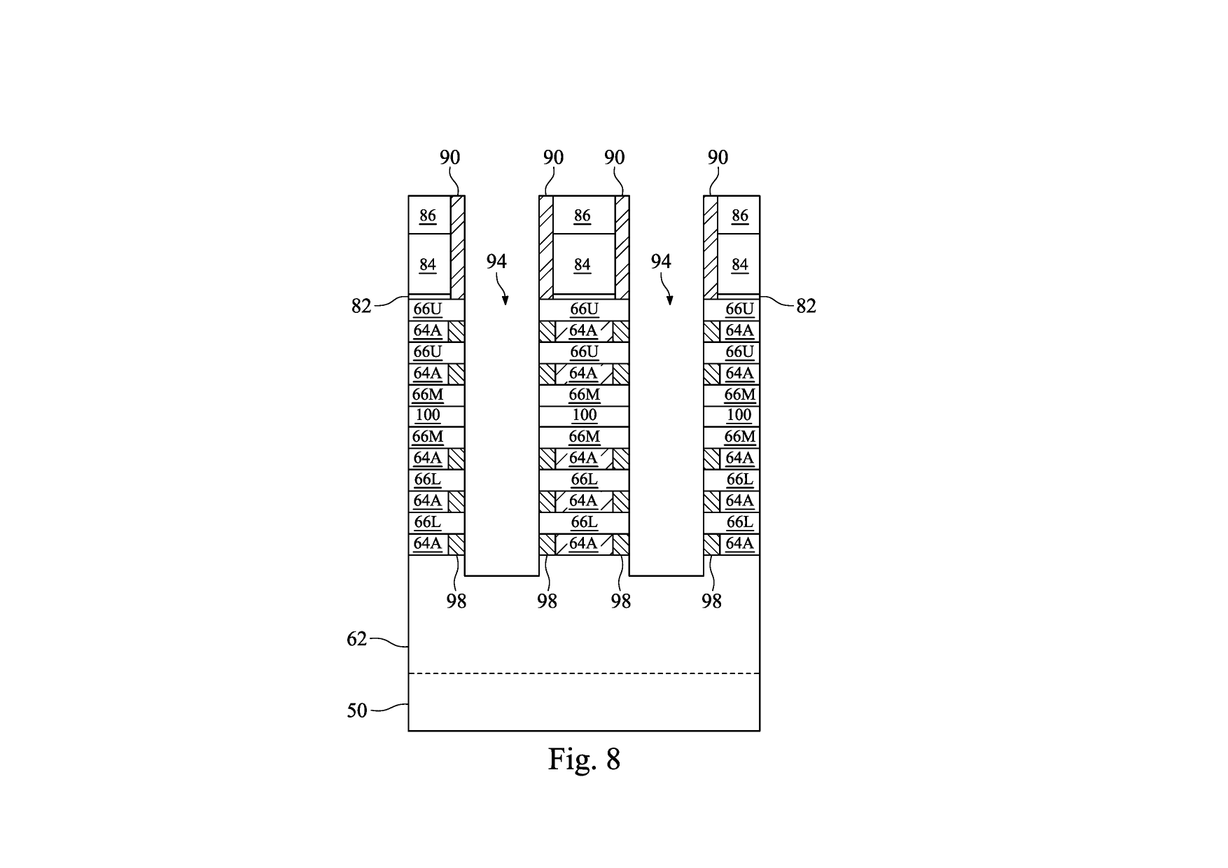

In FIG. 8, inner spacers 98 are formed in the sidewall recesses 96A and on the sidewalls of the remaining portions of the first dummy nanostructures 64A. As subsequently described in greater detail, source/drain regions will be subsequently formed in the source/drain recesses 94, and the first dummy nanostructures 64A will be replaced with corresponding gate structures. The inner spacers 98 act as isolation features between the subsequently formed source/drain regions and the subsequently formed gate structures. Further, the inner spacers 98 may be used to prevent damage to the subsequently formed source/drain regions by subsequent etch processes, such as etch processes used to form gate structures. Additionally, isolation structures 100 are formed in the openings 96B and between the middle semiconductor nanostructures 66M. The isolation structures 100 and the middle semiconductor nanostructures 66M will define the boundaries of the lower nanostructure-FETs and the upper nanostructure-FETs.

The inner spacers 98 and the isolation structures 100 may be formed by conformally forming an insulating material in the source/drain recesses 94, the sidewall recesses 96A, and the openings 96B, and then subsequently etching the insulating material. The insulating material may be a carbon-containing dielectric material, such as silicon oxycarbonitride, silicon oxycarbide, silicon oxynitride, or the like. Other low-dielectric constant (low-k) materials having a k-value less than about 3.5 may be utilized. The insulating material may be formed by a deposition process, such as ALD, CVD, or the like. The etching of the insulating material may be anisotropic. For example, the etch process may be a dry etch such as a RIE, a NBE, or the like. The insulating material, when etched, has portions remaining in the sidewall recesses 96A (thus forming the inner spacers 98) and has portions remaining in the openings 96B (thus forming the isolation structures 100).

Although outer sidewalls of the inner spacers 98 and the isolation structures 100 are illustrated as being flush with sidewalls of the semiconductor nanostructures 66, the outer sidewalls of the inner spacers 98 and the isolation structures 100 may extend beyond or be recessed from sidewalls of the semiconductor nanostructures 66. Thus, the inner spacers 98 and the isolation structures 100 may partially fill, completely fill, or overfill the sidewall recesses 96A and the openings 96B, respectively. Moreover, although the sidewalls of the inner spacers 98 and the isolation structures 100 are illustrated as being straight, those sidewalls may be concave or convex.

The isolation structures 100 have similar dimensions as the second dummy nanostructures 64B they replaced. Accordingly, the isolation structures 100 may have a large thickness, such as a greater thickness than the semiconductor nanostructures 66 and the first dummy nanostructures 64A, or the isolation structures 100 may have a small thickness, such as a lesser thickness than the semiconductor nanostructures 66 and the first dummy nanostructures 64A. In some embodiments, the isolation structures 100 are from 60% to 90% thinner than the semiconductor nanostructures 66 and the isolation structures 100 are from 40% to 90% thinner than the first dummy nanostructures 64A.

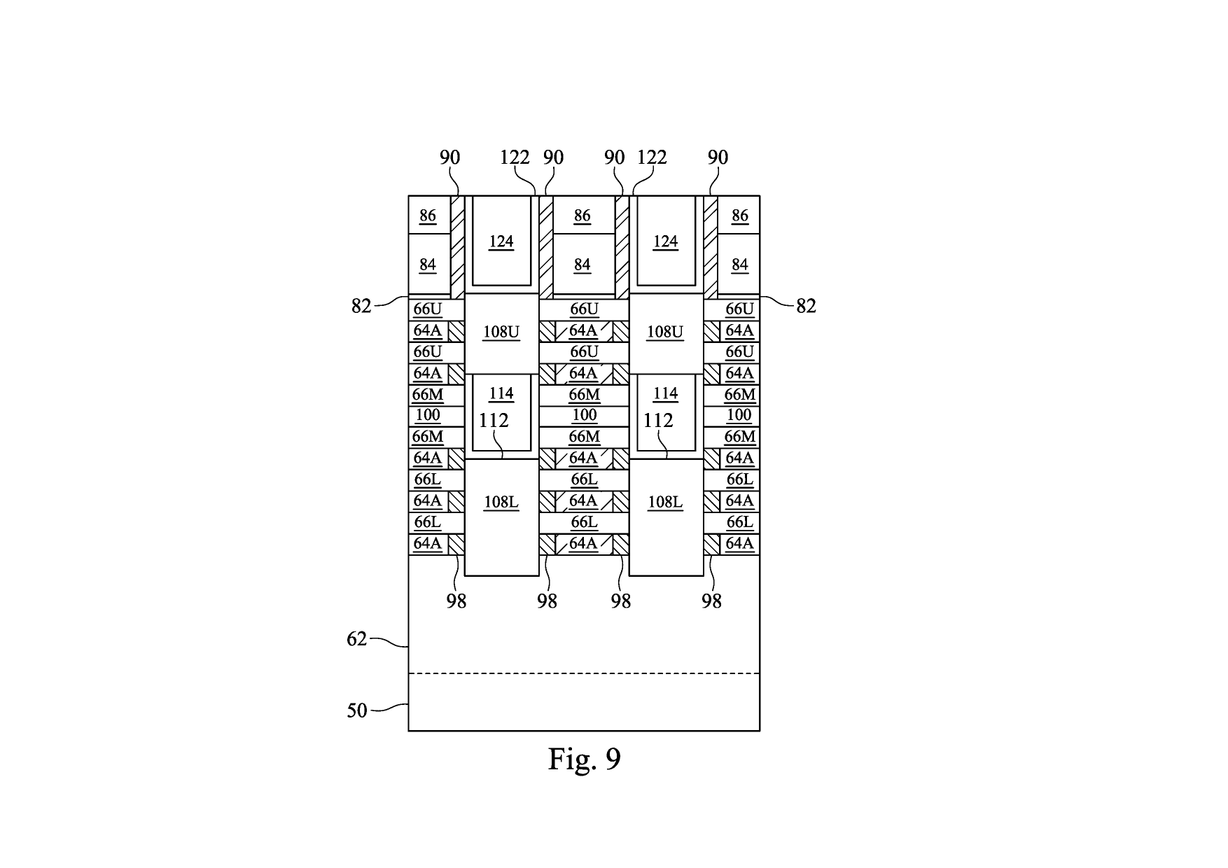

In FIG. 9, lower epitaxial source/drain regions 108L and upper epitaxial source/drain regions 108U are formed in the source/drain recesses 94. A first contact etch stop layer (CESL) 112 and/or a first inter-layer dielectric (ILD) 114 may also be formed in the source/drain recesses 94. The first ILD 114 is between the upper epitaxial source/drain regions 108U and the lower epitaxial source/drain regions 108L. The lower epitaxial source/drain regions 108L are for lower nanostructure-FETs of the CFETs, and the upper epitaxial source/drain regions 108U are for upper nanostructure-FETs of the CFETs. The first ILD 114 thus acts as isolation regions to prevent shorting of the lower and upper nanostructure-FETs. Additionally, a second CESL 122 and/or a second ILD 124 may be formed on the upper epitaxial source/drain regions 108U.

The lower epitaxial source/drain regions 108L are in contact with the lower semiconductor nanostructures 66L and are not in contact with the upper semiconductor nanostructures 66U. In some embodiments, the lower epitaxial source/drain regions 108L exert stress in the respective channel regions of the lower semiconductor nanostructures 66L, thereby improving performance. The lower epitaxial source/drain regions 108L are formed in the source/drain recesses 94 such that each stack of the lower semiconductor nanostructures 66L is disposed between respective neighboring pairs of the lower epitaxial source/drain regions 108L. In some embodiments, the inner spacers 98 are used to separate the lower epitaxial source/drain regions 108L from the first dummy nanostructures 64A, which will be replaced with gate structures in subsequent processes.

The lower epitaxial source/drain regions 108L are epitaxially grown in the lower portions of the source/drain recesses 94. For example, the lower epitaxial source/drain regions 108L may be grown laterally from exposed sidewalls of the lower semiconductor nanostructures 66L, as well as bottom surfaces of the fins 62/substrate 50 in the source/drain recesses 94. During the epitaxy of the lower epitaxial source/drain regions 108L, the middle semiconductor nanostructures 66M and/or the upper semiconductor nanostructures 66U may be masked to prevent undesired epitaxial growth on the middle semiconductor nanostructures 66M and/or the upper semiconductor nanostructures 66U. After the lower epitaxial source/drain regions 108L are grown, the masks on the middle semiconductor nanostructures 66M and/or the upper semiconductor nanostructures 66U may then be removed. The lower epitaxial source/drain regions 108L have a conductivity type that is suitable for the device type of the lower nanostructure-FETs. In some embodiments, the lower epitaxial source/drain regions 108L are n-type source/drain regions. For example, if the lower semiconductor nanostructures 66L are silicon, the lower epitaxial source/drain regions 108L may include materials exerting a tensile strain on the lower semiconductor nanostructures 66L, such as silicon, carbon-doped silicon, phosphorous-doped silicon, silicon phosphide, silicon arsenide, or the like. In some embodiments, the lower epitaxial source/drain regions 108L are p-type source/drain regions. For example, if the lower semiconductor nanostructures 66L are silicon-germanium, the lower epitaxial source/drain regions 108L may include materials exerting a compressive strain on the lower semiconductor nanostructures 66L, such as silicon-germanium, boron-doped silicon-germanium, boron-doped silicon, germanium, germanium tin, or the like. The lower epitaxial source/drain regions 108L may have surfaces raised from respective upper surfaces of the lower semiconductor nanostructures 66L and may have facets.

The lower epitaxial source/drain regions 108L may be implanted with dopants to form source/drain regions, similar to the process previously discussed for forming lightly-doped source/drain regions, followed by an anneal. The source/drain regions may have an impurity concentration in the range of 10¹⁹ atoms/cm³ and 10²¹ atoms/cm³. The n-type and/or p-type impurities for source/drain regions may be any of the impurities previously discussed. In some embodiments, the lower epitaxial source/drain regions 108L are in situ doped during growth.

As a result of the epitaxy processes used to form the lower epitaxial source/drain regions 108L, upper surfaces of the lower epitaxial source/drain regions 108L have facets which expand laterally outward beyond sidewalls of the nanostructures 64, 66. In some embodiments, adjacent lower epitaxial source/drain regions 108L remain separated after the epitaxy process is completed. In other embodiments, these facets cause adjacent lower epitaxial source/drain regions 108L of a same nanostructure-FET to merge.

The first ILD 114 is formed over the lower epitaxial source/drain regions 108L. The first ILD 114 may be formed of a dielectric material, which may be deposited by any suitable method, such as CVD, plasma-enhanced chemical vapor deposition (PECVD), or FCVD. Dielectric materials may include phospho-silicate glass (PSG), boro-silicate glass (BSG), boron-doped phospho-silicate glass (BPSG), undoped silicate glass (USG), or the like. Other dielectric materials formed by any acceptable process may be used.

The first CESL 112 may be formed between the first ILD 114 and the lower epitaxial source/drain regions 108L. The first CESL 112 may be formed of a dielectric material having a high etching selectivity to the dielectric material of the first ILD 114, such as silicon nitride, silicon oxide, silicon oxynitride, or the like, which may be formed by any suitable deposition process, such as CVD, ALD, or the like.

The first CESL 112 and/or the first ILD 114 may be formed by depositing a material for the first CESL 112 and depositing a material for the first ILD 114, followed by an etch-back process. In some embodiments, the first ILD 114 is initially etched, leaving the first CESL 112 unetched. An anisotropic etching process is then performed to remove the portions of the first CESL 112 that are higher than the first ILD 114. After the recessing, the sidewalls of the upper semiconductor nanostructures 66U are exposed.

The upper epitaxial source/drain regions 108U are in contact with the upper semiconductor nanostructures 66U and are not in contact with the lower semiconductor nanostructures 66L. In some embodiments, the upper epitaxial source/drain regions 108U exert stress in the respective channel regions of the upper semiconductor nanostructures 66U, thereby improving performance. The upper epitaxial source/drain regions 108U are formed in the source/drain recesses 94 such that each stack of the upper semiconductor nanostructures 66U is disposed between respective neighboring pairs of the upper epitaxial source/drain regions 108U. In some embodiments, the inner spacers 98 are used to separate the upper epitaxial source/drain regions 108U from the first dummy nanostructures 64A, which will be replaced with gate structures in subsequent processes.

The upper epitaxial source/drain regions 108U are epitaxially grown in the upper portions of the source/drain recesses 94. For example, the upper epitaxial source/drain regions 108U may be grown laterally from exposed sidewalls of the upper semiconductor nanostructures 66U. The upper epitaxial source/drain regions 108U have a conductivity type that is suitable for the device type of the upper nanostructure-FETs. The conductivity type of the upper epitaxial source/drain regions 108U may be opposite the conductivity type of the lower epitaxial source/drain regions 108L. Put another way, the upper epitaxial source/drain regions 108U may be oppositely doped from the lower epitaxial source/drain regions 108L. In some embodiments, the upper epitaxial source/drain regions 108U are n-type source/drain regions. For example, if the upper semiconductor nanostructures 66U are silicon, the upper epitaxial source/drain regions 108U may include materials exerting a tensile strain on the upper semiconductor nanostructures 66U, such as silicon, carbon-doped silicon, phosphorous-doped silicon, silicon phosphide, silicon arsenide, or the like. In some embodiments, the upper epitaxial source/drain regions 108U are p-type source/drain regions. For example, if the upper semiconductor nanostructures 66U are silicon-germanium, the upper epitaxial source/drain regions 108U may include materials exerting a compressive strain on the upper semiconductor nanostructures 66U, such as silicon-germanium, boron-doped silicon-germanium, boron-doped silicon, germanium, germanium tin, or the like. The upper epitaxial source/drain regions 108U may have surfaces raised from respective upper surfaces of the upper semiconductor nanostructures 66U and may have facets.

The upper epitaxial source/drain regions 108U may be implanted with dopants to form source/drain regions, similar to the process previously discussed for forming lightly-doped source/drain regions, followed by an anneal. The source/drain regions may have an impurity concentration in the range of 10¹⁹ atoms/cm³ and 10²¹ atoms/cm³. The n-type and/or p-type impurities for source/drain regions may be any of the impurities previously discussed. In some embodiments, the upper epitaxial source/drain regions 108U are in situ doped during growth.

As a result of the epitaxy processes used to form the upper epitaxial source/drain regions 108U, upper surfaces of the upper epitaxial source/drain regions 108U have facets which expand laterally outward beyond sidewalls of the nanostructures 64, 66. In some embodiments, adjacent upper epitaxial source/drain regions 108U remain separated after the epitaxy process is completed. In other embodiments, these facets cause adjacent upper epitaxial source/drain regions 108U of a same nanostructure-FET to merge.

The second ILD 124 is deposited over the upper epitaxial source/drain regions 108U. The second ILD 124 may be formed of a dielectric material, which may be deposited by any suitable method, such as CVD, plasma-enhanced chemical vapor deposition (PECVD), or FCVD. Dielectric materials may include phospho-silicate glass (PSG), boro-silicate glass (BSG), boron-doped phospho-silicate glass (BPSG), undoped silicate glass (USG), or the like. Other dielectric materials formed by any acceptable process may be used.

The second CESL 122 may be formed between the second ILD 124 and the upper epitaxial source/drain regions 108U. The second CESL 122 may be formed of a dielectric material having a high etching selectivity to the dielectric material of the second ILD 124, such as, silicon nitride, silicon oxide, silicon oxynitride, or the like, which may be formed by any suitable deposition process, such as CVD, ALD, or the like.

The second CESL 122 and/or the second ILD 124 may be formed by depositing a material for the second CESL 122 and depositing a material for the second ILD 124. A removal process is then performed to level the top surfaces of the second ILD 124 with the top surfaces of the gate spacers 90 and the masks 86 (if present) or the dummy gates 84. In some embodiments, a planarization process such as a chemical mechanical polish (CMP), an etch-back process, combinations thereof, or the like may be utilized. The planarization process may also remove the masks 86 on the dummy gates 84, and portions of the gate spacers 90 along sidewalls of the masks 86. After the planarization process, top surfaces of the second ILD 124, the gate spacers 90, and the masks 86 (if present) or the dummy gates 84 are substantially coplanar (within process variations). Accordingly, the top surfaces of the masks 86 (if present) or the dummy gates 84 are exposed through the second ILD 124. In the illustrated embodiment, the masks 86 remain after the removal process. In other embodiments, the masks 86 are removed such that the top surfaces of the dummy gates 84 are exposed through the second ILD 124.

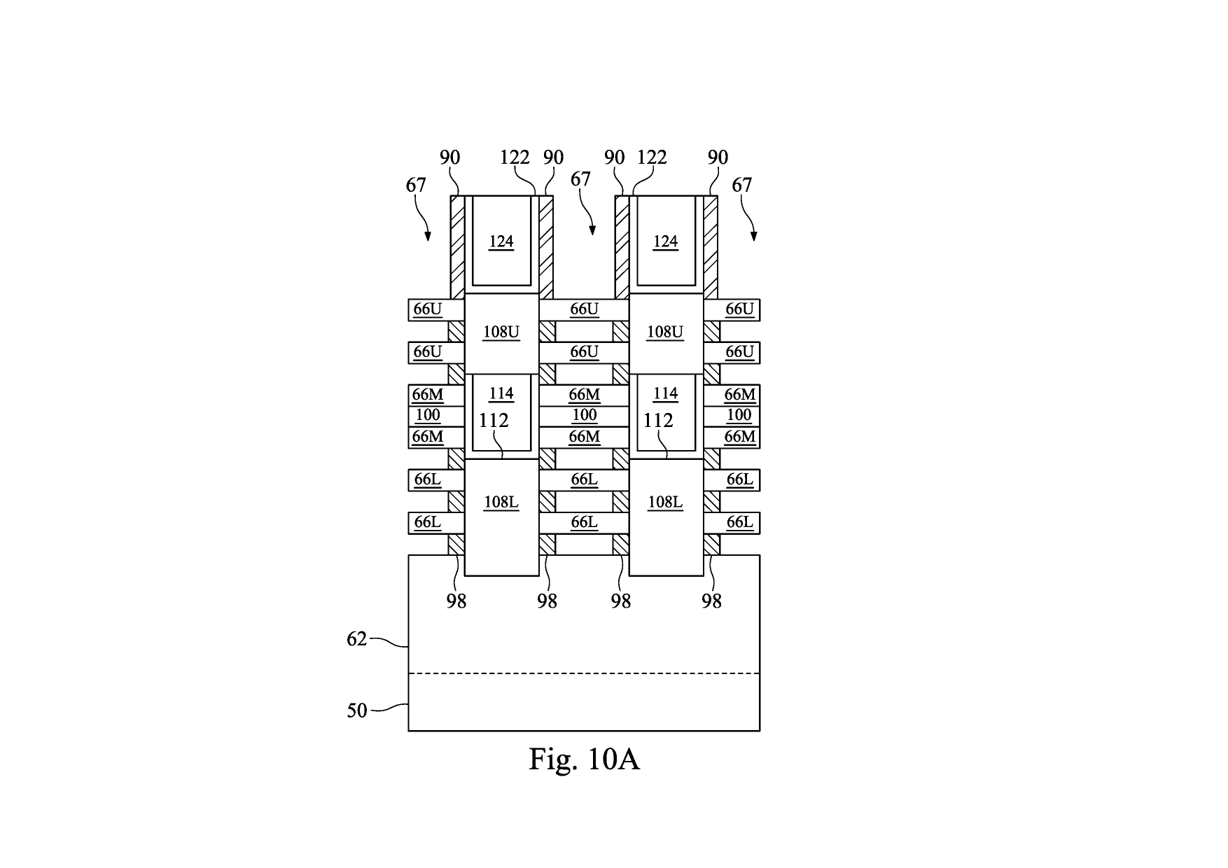

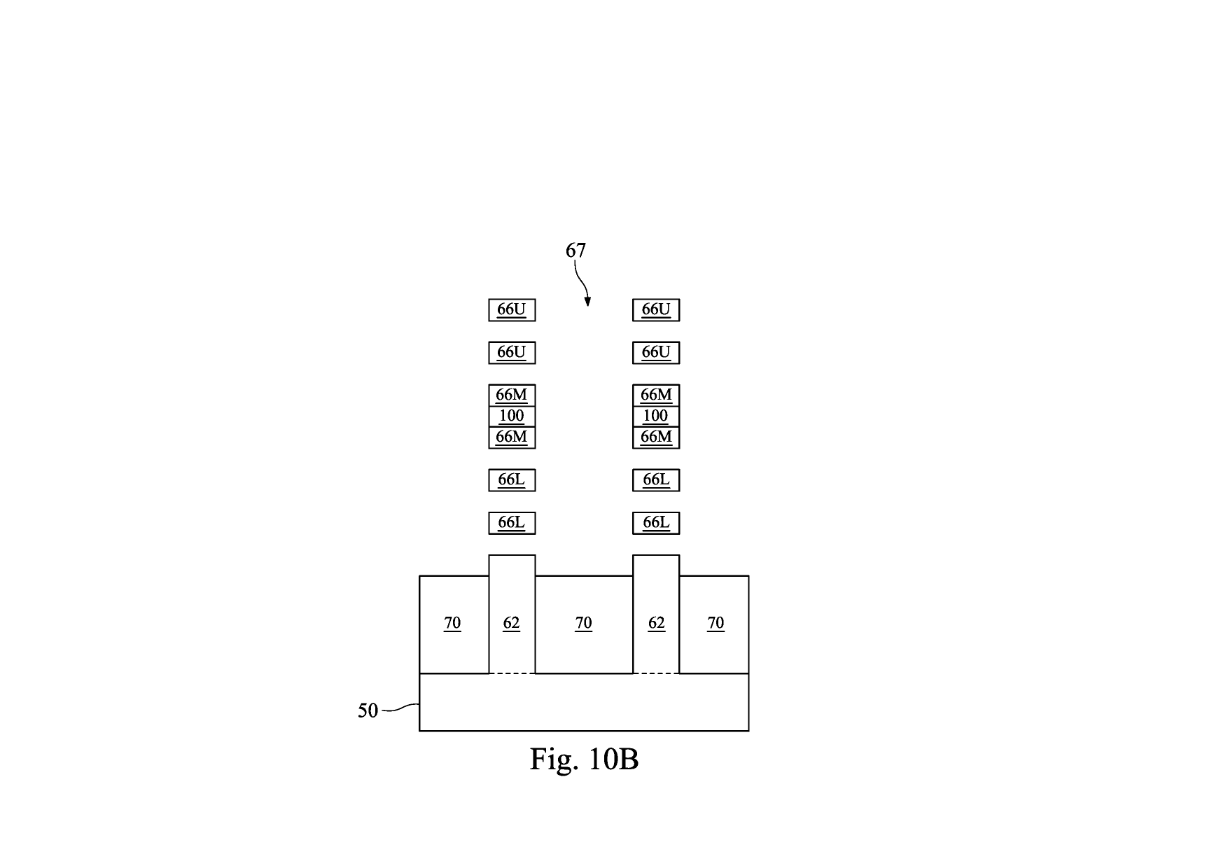

In FIGS. 10A and 10B, the dummy gates 84 are removed in one or more etching steps, so that recesses 67 are formed between the gate spacers 90. Portions of the dummy dielectrics 82 in the recesses 67 are also removed. In some embodiments, the dummy gates 84 and the dummy dielectrics 82 are removed by an anisotropic dry etch process. For example, the etching process may include a dry etch process using reaction gas(es) that selectively etch the material of the dummy gates 84 at a faster rate than the materials of the second ILD 124, the isolation structures 100, the inner spacers 98, and the gate spacers 90. Each recess 67 between the gate spacers 90 exposes and/or overlies portions of nanostructures 64, 66 which act as the channel regions in the resulting devices. The portions of the nanostructures 64, 66 which act as the channel regions are disposed between neighboring pairs of the lower epitaxial source/drain regions 108L or between neighboring pairs of the upper epitaxial source/drain regions 108U. During the removal, the dummy dielectrics 82 may be used as etch stop layers when the dummy gates 84 are etched. The dummy dielectrics 82 may then be removed after the removal of the dummy gates 84.

The remaining portions of the first dummy nanostructures 64A are then removed to extend the recesses 67 and form openings in regions between the semiconductor nanostructures 66. The remaining portions of the first dummy nanostructures 64A can be removed by any acceptable etch process that selectively etches the material of the first dummy nanostructures 64A at a faster rate than the materials of the semiconductor nanostructures 66, the inner spacers 98, and the isolation structures 100. The etching may be isotropic. For example, when the first dummy nanostructures 64A are formed of silicon-germanium, the semiconductor nanostructures 66 are formed of silicon, the inner spacers 98 are formed of silicon oxycarbonitride, and the isolation structures 100 are formed of silicon oxycarbonitride, the etch process may be a wet etch using tetramethylammonium hydroxide (TMAH), ammonium hydroxide (NH₄OH), or the like. In some embodiments, a trim process (not separately illustrated) is performed to decrease the thicknesses of the exposed portions of the semiconductor nanostructures 66 and expand the openings between the semiconductor nanostructures 66.

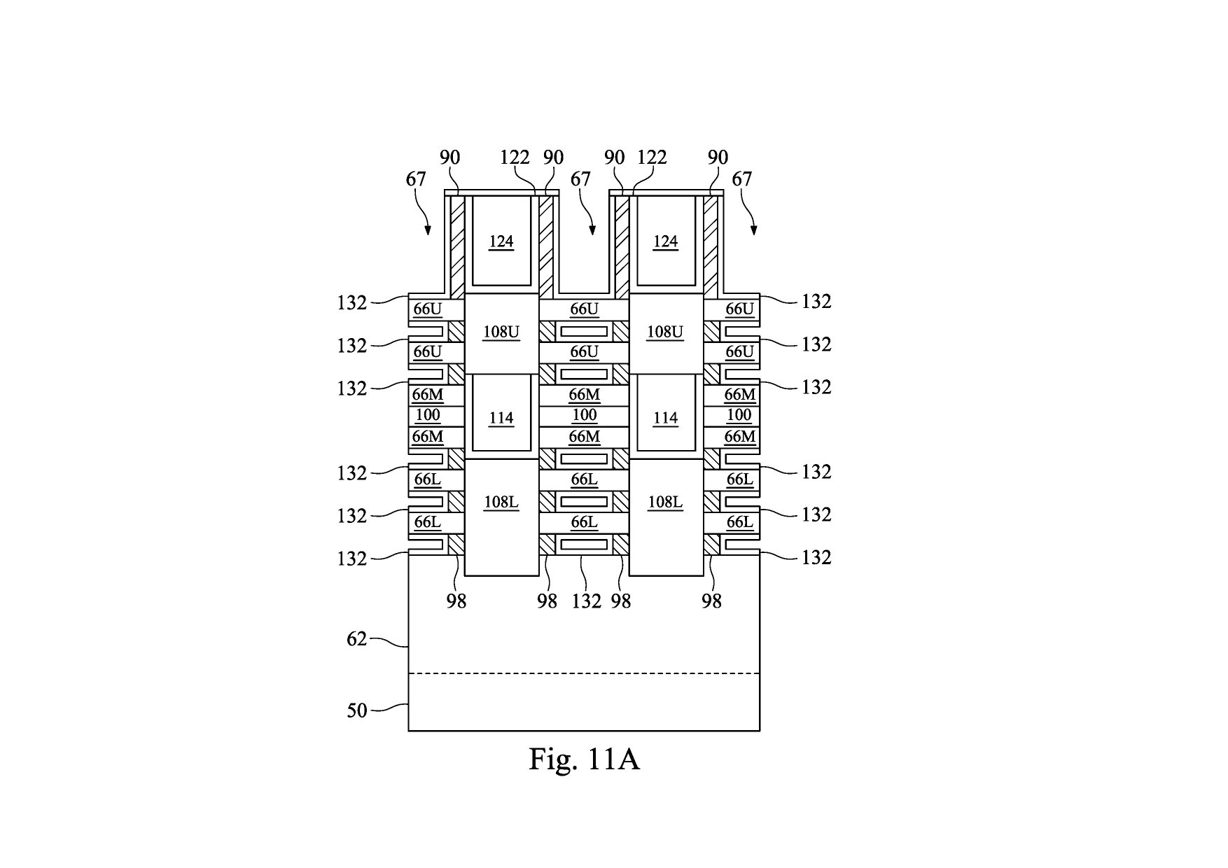

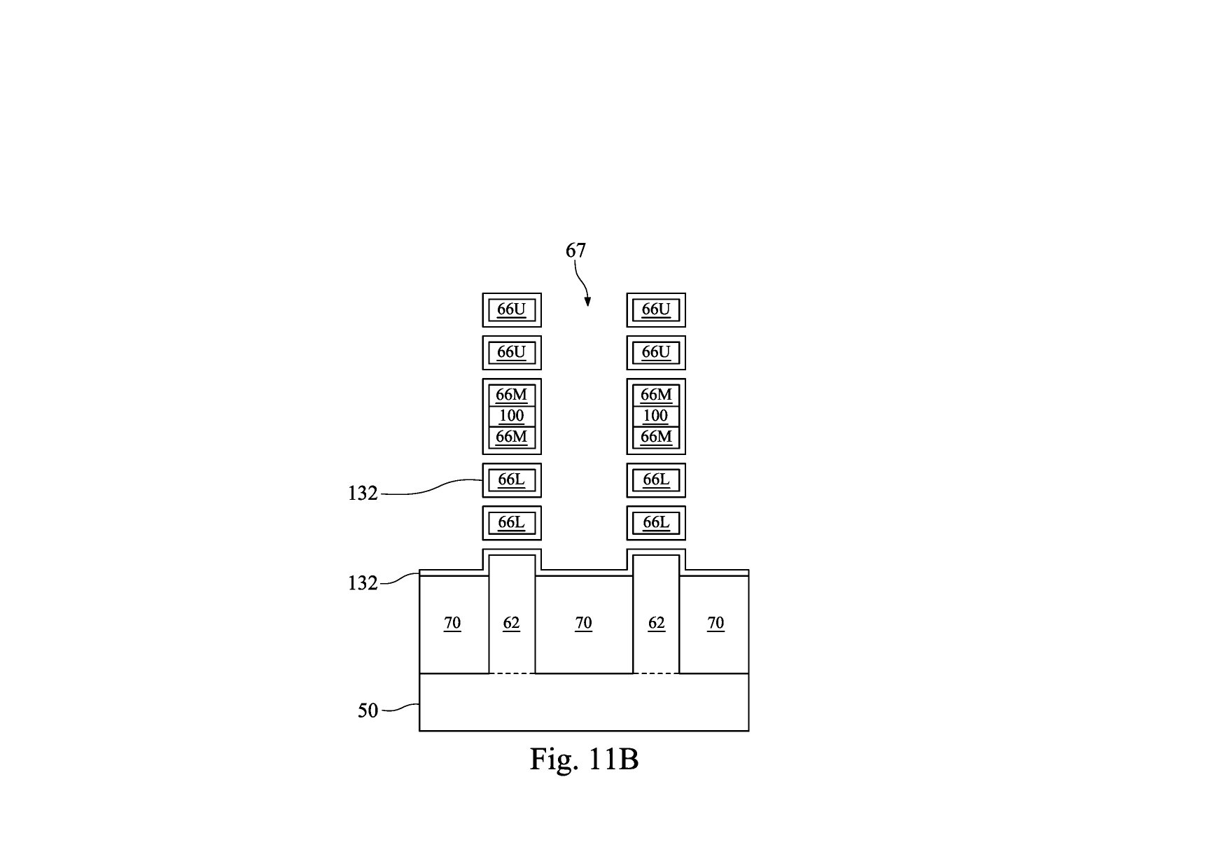

In FIGS. 11A and 11B, gate dielectrics 132 may be deposited in the recesses 67, such as between the gate spacers 90 and the openings between the semiconductor nanostructures 66. The gate dielectrics 132 may also be deposited on the top surfaces of the second ILD 124 and the gate spacers 90. The gate dielectrics 132 may include one or more gate dielectric layer(s) disposed around the lower semiconductor nanostructures 66L, the upper semiconductor nanostructures 66U, and the isolation structures 100. Specifically, the gate dielectrics 132 are disposed on the top surfaces of the fins 62; on the top surfaces, the sidewalls, and the bottom surfaces of the semiconductor nanostructures 66; and on the sidewalls of the gate spacers 90. The gate dielectrics 132 wrap around all (e.g., four) sides of the semiconductor nanostructures 66. The gate dielectrics 132 may be formed of an oxide such as silicon oxide or a metal oxide, a silicate such as a metal silicate, combinations thereof, multi-layers thereof, or the like. Additionally or alternatively, the gate dielectrics 132 may be formed of a high-k dielectric material (e.g., dielectric materials having a k-value greater than about 7.0), such as a metal oxide or a silicate of hafnium, aluminum, zirconium, lanthanum, manganese, barium, titanium, lead, and combinations thereof. The dielectric material(s) of the gate dielectrics 132 may be formed by molecular-beam deposition (MBD), ALD, PECVD, or the like. Although single-layered gate dielectrics 132 are illustrated, the gate dielectrics 132 may include any number of interfacial layers and any number of main layers. For example, the gate dielectrics 132 may include an interfacial layer that may be selectively formed on surfaces of the lower semiconductor nanostructures 66L and the upper semiconductor nanostructures 66U, and an overlying high-k dielectric layer over the interfacial layer. The interfacial layer may not be formed on surfaces of the isolation structures 100. In addition, depending on a material of the middle semiconductor nanostructures 66M, the interfacial layer may not be formed on surfaces of the middle semiconductor nanostructures 66M.

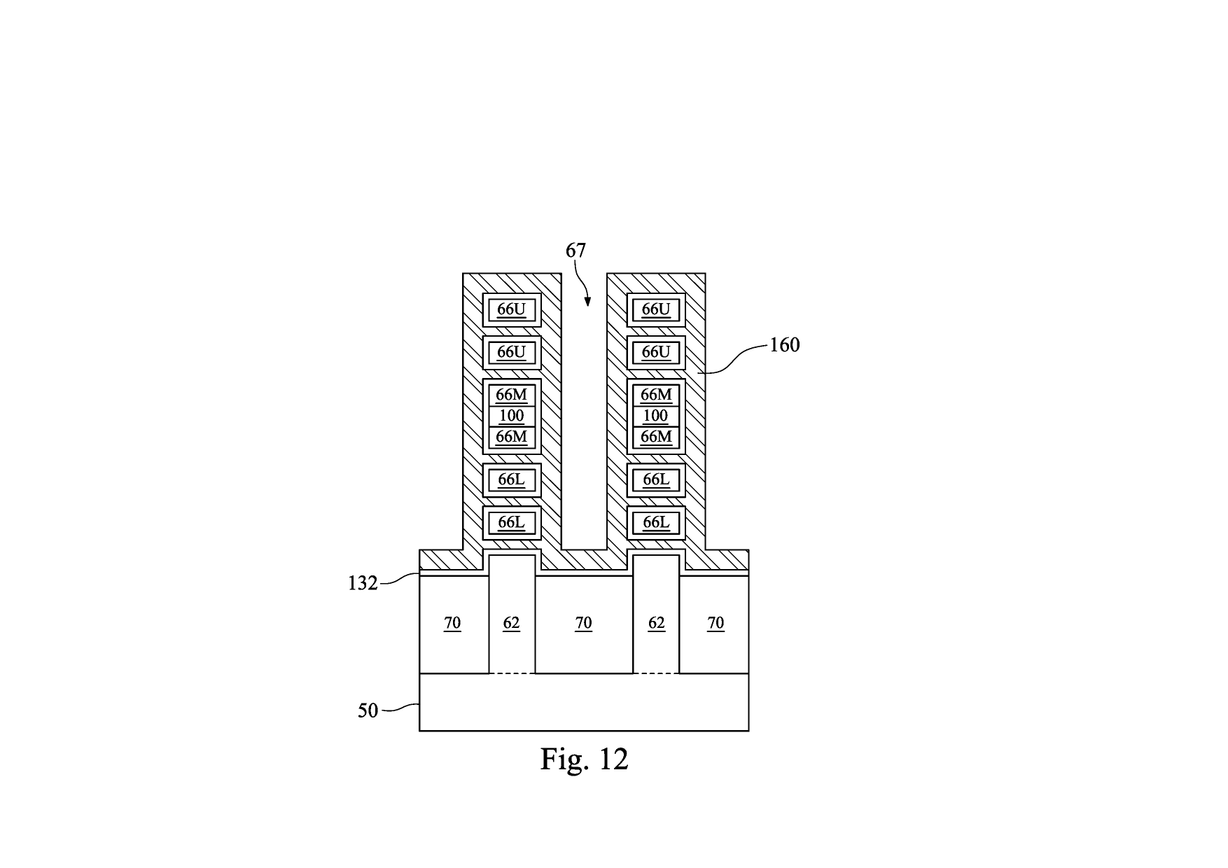

In FIG. 12, a dielectric layer 160 is deposited in the recesses 67 and over the structures illustrated in FIGS. 11A and 11B using a conformal deposition process, such as CVD, ALD, or the like. The dielectric layer 160 may comprise a material such as aluminum oxide, or the like. The dielectric layer 160 may be formed over the gate dielectrics 132 and around the lower semiconductor nanostructures 66L, the upper semiconductor nanostructures 66U, and the isolation structures 100. The dielectric layer 160 may fill the openings between the semiconductor nanostructures 66 and openings between bottommost semiconductor nanostructures 66 and the fins 62. In an embodiment, the dielectric layer 160 is also formed over the isolation regions 70.

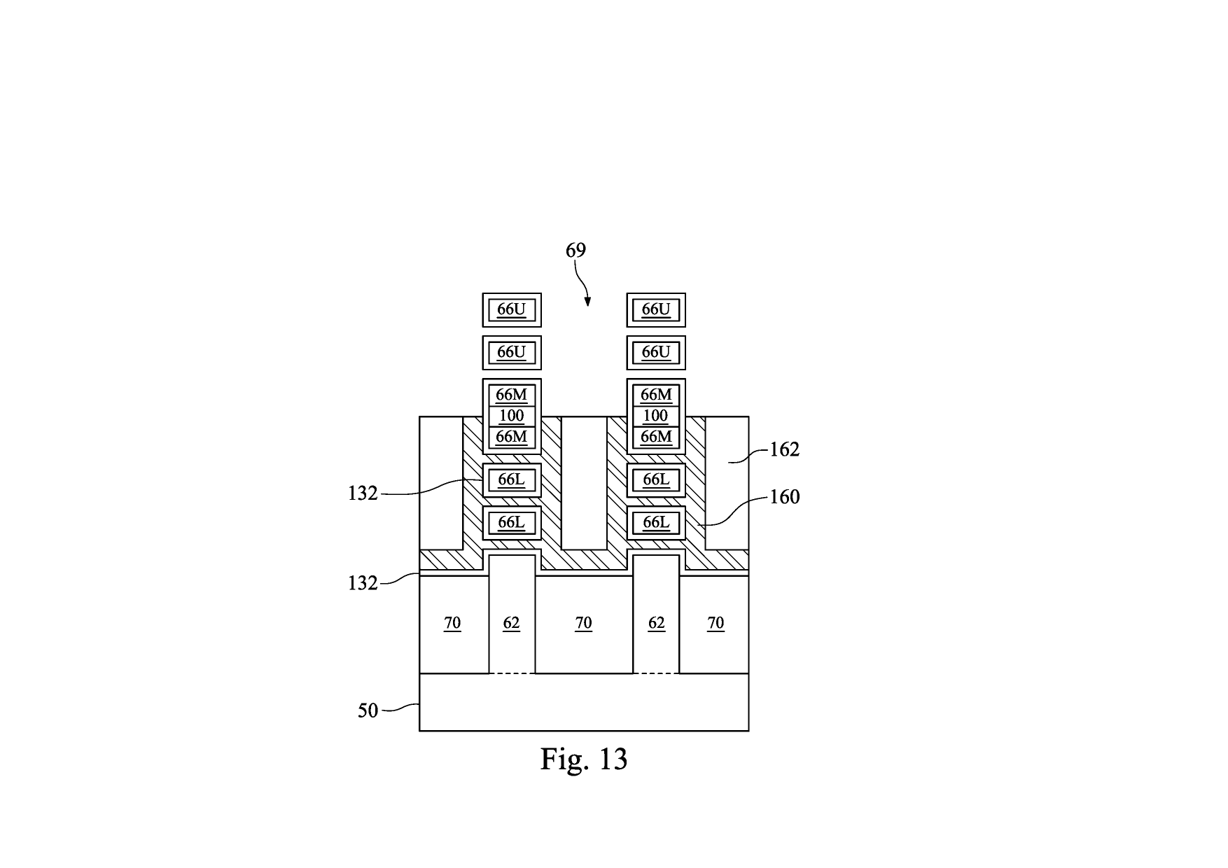

In FIG. 13, a Bottom Anti-Reflective Coating (BARC) layer 162 is formed in the recesses 67, such as over top surfaces and sidewalls of the dielectric layer 160 in the recesses 67. In some embodiments, the BARC layer 162 is formed over the structure shown in FIG. 12, using any suitable process such as spin-coating, CVD, PECVD, or the like. In an embodiment, the BARC layer 162 may fill the recesses 67. After the formation of the BARC layer 162, portions of the BARC layer 162 may be disposed over top surfaces of the second ILD 124 and the gate spacers 90. After the formation of the BARC layer 162, a suitable etch-back process (e.g., a dry etch process or a wet etch process) may be performed to form recesses 69 that are formed between the gate spacers 90. For example, the etch-back process may remove top portions of the BARC layer 162 that are over the second ILD 124, the gate spacers 90, and over the top surfaces of the dielectric layer 160. In addition, the etch-back process may extend the recesses 69 and remove portions of the BARC layer 162 that are adjacent to sidewalls of the dielectric layer 160. For example, the etch-back process may remove portions of the BARC layer 162 that are adjacent to sidewalls of portions of the dielectric layer 160 that are above the isolation structures 100. In addition, the etch-back process may remove portions of the BARC layer 162 that are adjacent to sidewalls of portions of the dielectric layer 160 that are disposed on sidewalls of the isolation structures 100. In this way, after the etch-back process is performed, top surfaces of the dielectric layer 160 in the recesses 69, the sidewalls of the portions of the dielectric layer 160 that are above the isolation structures 100, and the sidewalls of the portions of the dielectric layer 160 that are disposed on sidewalls of the isolation structures 100 are exposed. In an embodiment, after the etch-back process is performed, the portions of the dielectric layer 160 that are above the isolation structures 100 are above topmost surfaces of the BARC layer 162.

After the etch-back process is performed, an etching process is performed using remaining portions of the BARC layer 162 as an etching mask to remove the exposed portions of the dielectric layer 160 that are disposed above the topmost surface of the BARC layer 162. In an embodiment, the etching process may be an isotropic etching process, such as a thermal dry etch that is performed at elevated temperatures using a mixture of nitrogen and hydrogen gases. For example, the etching process may extend the recesses 69 by removing portions of the dielectric layer 160 that are disposed over topmost upper semiconductor nanostructures 66U, and between the upper semiconductor nanostructures 66U to form openings between the upper semiconductor nanostructures 66U. In an embodiment, after the etching process is performed, the topmost surfaces of the BARC layer 162 may be level with topmost surfaces of the dielectric layer 160. In an embodiment, after the etching process is performed, the topmost surfaces of the BARC layer 162 and the topmost surfaces of the dielectric layer 160 may be disposed above bottom surfaces of the isolation structures 100 and below top surfaces of the isolation structures 100.

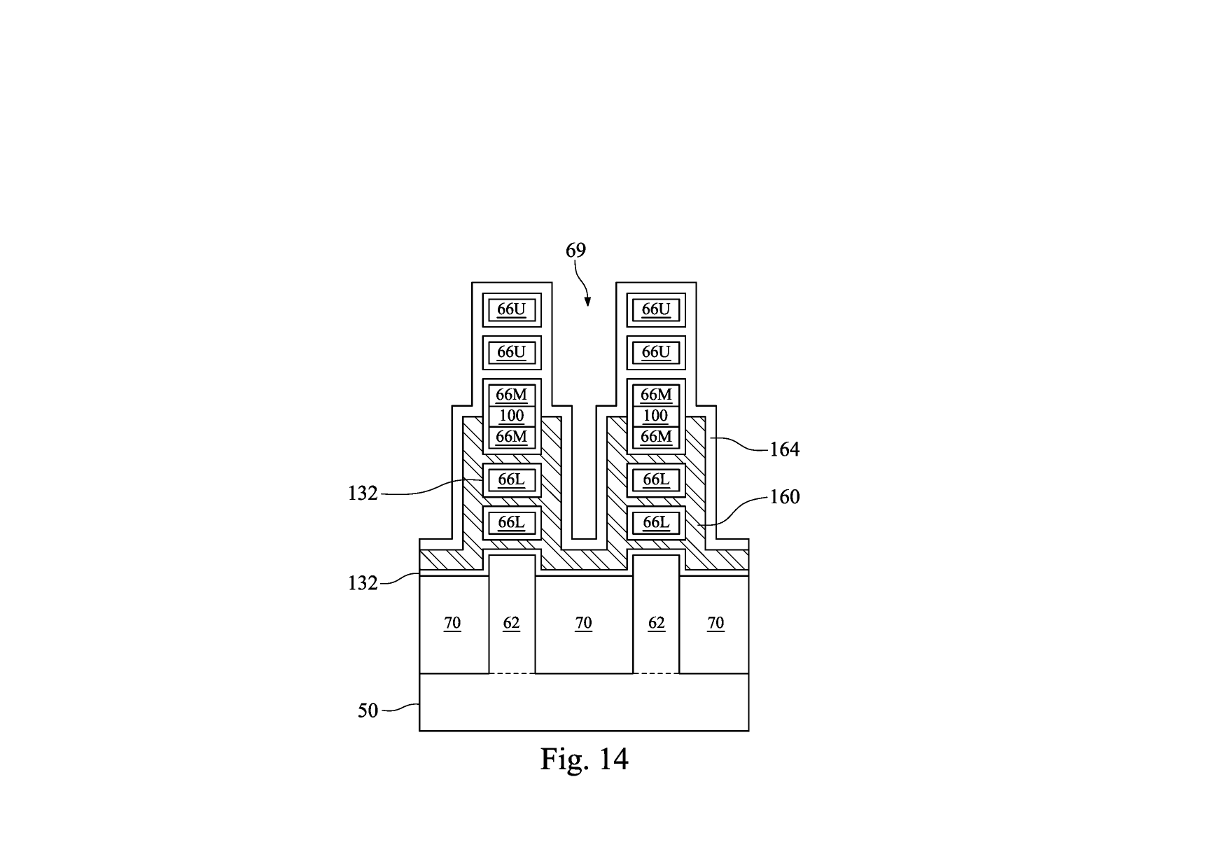

In FIG. 14, the BARC layer 162 is removed using a suitable ashing process to extend the recesses 69. In an embodiment, the ashing process may comprise exposing the BARC layer 162 to oxygen plasma, or the like. After the removal of the BARC layer 162, a metal-containing layer 164 may be deposited over the structure and in the recesses 69, such as over the dielectric layer 160, the gate dielectrics 132, and the semiconductor nanostructures 66. The metal-containing layer 164 may comprise titanium nitride, or the like, that is conformally deposited using a suitable process such as ALD, CVD, PVD, or the like. In an embodiment, the metal-containing layer 164 may be deposited over the gate dielectrics 132 and around the upper semiconductor nanostructures 66U to fill the openings between the upper semiconductor nanostructures 66U. In addition, the metal-containing layer 164 may be formed on top surfaces and sidewalls of the dielectric layer 160 and the gate spacers 90, and on top surfaces of the second ILD 124.

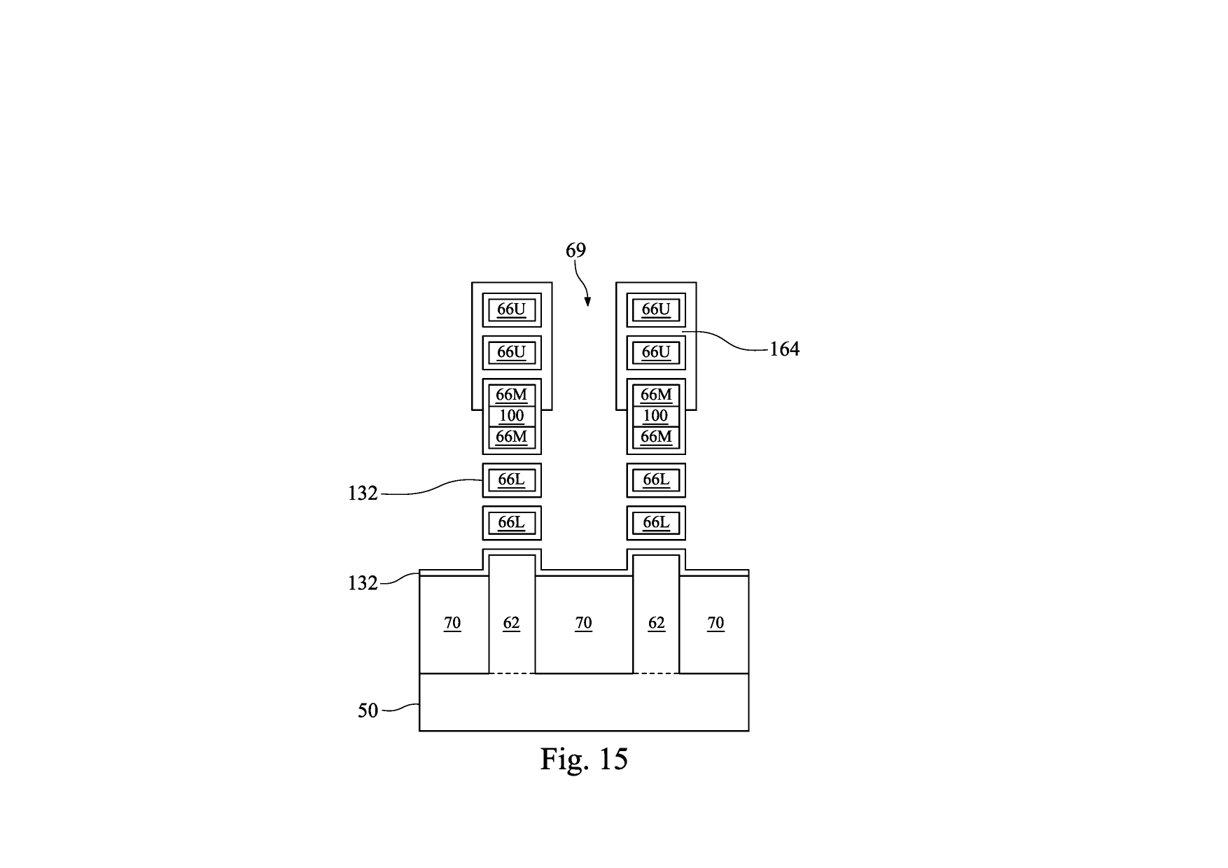

In FIG. 15, an etching process (e.g., a wet etching process using hydrogen peroxide (H₂O₂), ammonium hydroxide (NH₄OH), hydrochloric acid (HCl), or the like) is performed to remove portions of the metal-containing layer 164 that are disposed on sidewalls and top surfaces of the dielectric layer 160. In an embodiment, the etching process may also remove portions of the metal-containing layer 164 that are disposed on the top surfaces and sidewalls of the gate spacers 90, and on the top surfaces of the second ILD 124. After the etching process, the sidewalls and the top surfaces of the dielectric layer 160 may be exposed in the recesses 69. In an embodiment, after the etching process is performed, portions of the metal-containing layer 164 may remain disposed around and between the upper semiconductor nanostructures 66U. In addition, after the etching process is performed, portions of the metal-containing layer 164 may remain disposed on sidewalls of the middle semiconductor nanostructures 66M and the isolation structures 100. In an embodiment, after the etching process is performed, a bottommost surface of the metal-containing layer 164 is in contact with a topmost surface of the dielectric layer 160.

After performing the etching process to remove portions of the metal-containing layer 164, the dielectric layer 160 is removed by performing an etching process. Performing the etching process to remove the dielectric layer 160 may comprise performing an isotropic etching process, such as wet etching, or the like, using an acid or a base solution that includes ammonium hydroxide (NH₄OH), hydrochloric acid (HCl), or the like, as an etchant. The etching process may result in the forming of openings between the lower semiconductor nanostructures 66L in the recesses 69, and between the bottommost lower semiconductor nanostructures 66L and the fins 62.

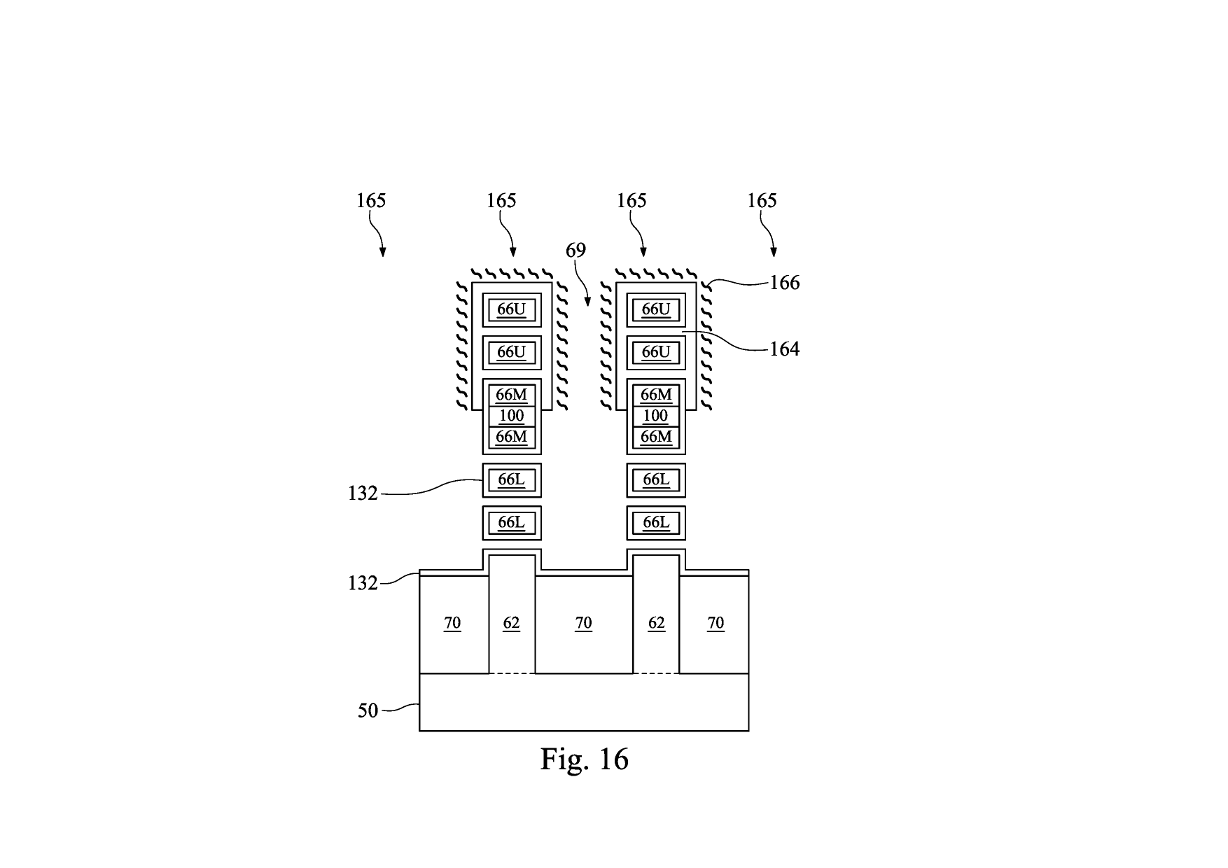

In FIG. 16, the structure shown previously in FIG. 15 is exposed to a molecular inhibitor 165. In an embodiment, the molecular inhibitor 165 may comprise an aniline, a derivative of aniline, an aldehyde, or the like. The molecular inhibitor 165 may be a small, low molecular weight organic compound that selectively adheres to and selectively passivates surfaces of the metal-containing layer 164 in the recesses 69. For example, the molecular inhibitor 165 may be introduced in the form of a gas or a liquid solution into a process chamber containing the structure shown previously in FIG. 15. The molecular inhibitor 165 may form a thin passivation layer 166 on the surfaces of the metal-containing layer 164, including on sidewalls, bottom surfaces, and top surfaces of the metal-containing layer 164. The passivation layer 166 may be able to selectively prevent the deposition of materials on the surfaces of the metal-containing layer 164 during subsequent deposition processes.

In an embodiment, the molecular inhibitor 165 may comprise an aniline, or a derivative of aniline such as 3,4-(methylenedioxy)aniline, aniline-2-sulfonic acid, N-(2-hydroxyethyl)aniline, 4-(trifluoromethyl)aniline, 4-(methylthio)aniline, 3-(methylthio)aniline, 3-(1-aminoethyl)aniline, 4-(octyloxy)aniline, 4-(piperidin-1-ylmethyl)aniline, p-toluidine, n-ethyl 4-fluoroaniline, 4-isopropylaniline, 4-nitroaniline, p-anisidine, 4-chloroaniline or 4-iodoaniline. In an embodiment, the molecular inhibitor 165 may comprise an aldehyde such as acetaldehyde, acrolein, butyraldehyde, crotonaldehyde, formaldehyde or propionaldehyde.

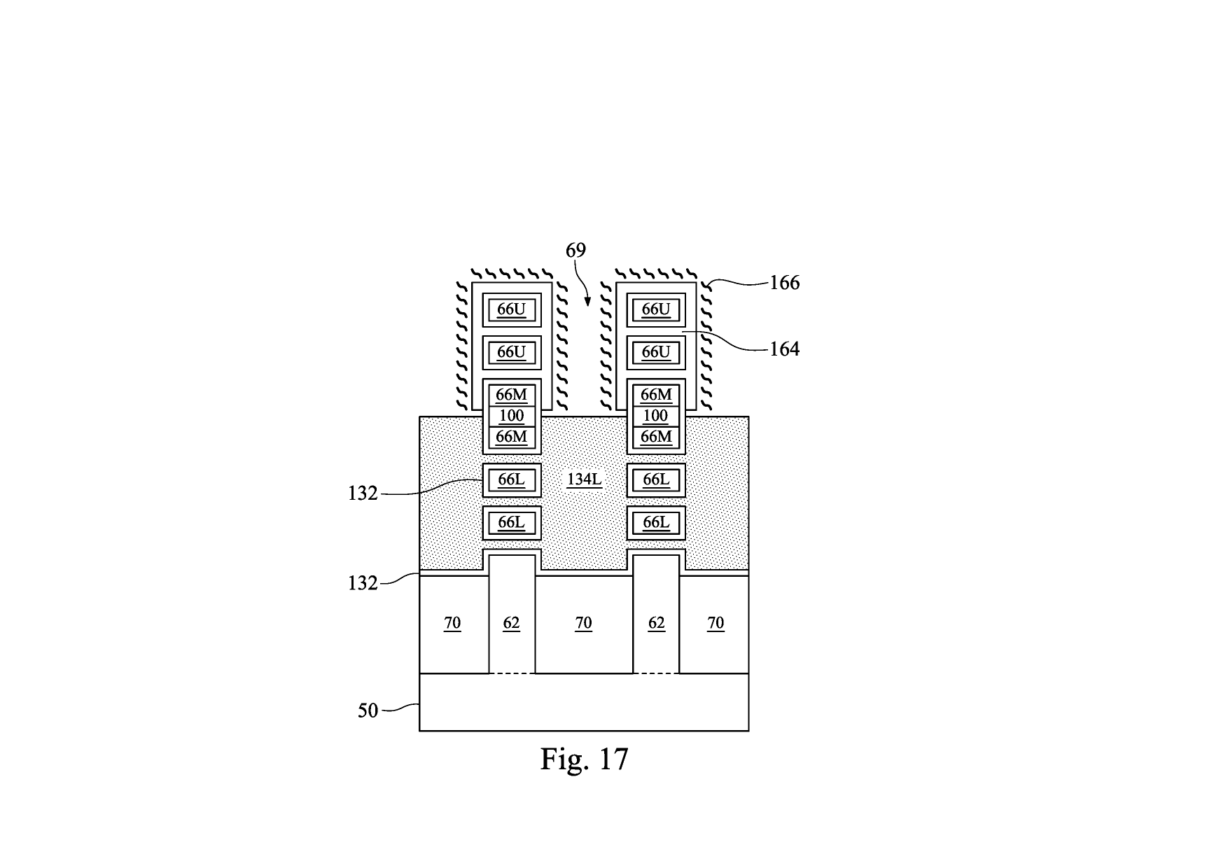

FIG. 17 illustrates the formation of lower gate electrodes 134L. The lower gate electrodes 134L may include one or more gate electrode layer(s) disposed over the gate dielectrics 132 and around the lower semiconductor nanostructures 66L. The lower gate electrodes 134L are disposed in the lower portions of the recesses 69 between the gate spacers 90 and in the openings between the lower semiconductor nanostructures 66L, and between the bottommost lower semiconductor nanostructures 66L and the fins 62. In an embodiment, top surfaces of the lower gate electrodes 134L are below top surfaces of the isolation structures 100. The lower gate electrodes 134L may be formed of a metal-containing material such as tungsten, titanium, titanium nitride, tantalum, tantalum nitride, tantalum carbide, aluminum, ruthenium, cobalt, combinations thereof, multi-layers thereof, or the like. For example, in an embodiment, the lower semiconductor nanostructures 66L may form channel regions for subsequently formed lower nanostructure-FETs. In an embodiment in which the subsequently formed lower nanostructure-FETs are p-type devices, the lower gate electrodes 134L may be formed of a metal-containing material such as ruthenium, titanium nitride, tungsten nitride, tantalum nitride, or the like. Although single-layered gate electrodes are illustrated, the lower gate electrodes 134L may include any number of work function tuning layers, any number of barrier layers, any number of glue layers, and a fill material.

The lower gate electrodes 134L are formed of material(s) that are suitable for the device type of the lower nanostructure-FETs. For example, the lower gate electrodes 134L may include one or more work function tuning layer(s) formed of work function tuning metal(s) that are suitable for the device type of the lower nanostructure-FETs. In some embodiments, the lower gate electrodes 134L include a p-type work function tuning layer, which may be formed of a p-type work function tuning metal such as titanium nitride, tantalum nitride, combinations thereof, or the like. Additionally or alternatively, the lower gate electrodes 134L may include a dipole-inducing element that is suitable for the device type of the lower nanostructure-FETs. Acceptable dipole-inducing elements include lanthanum, aluminum, scandium, ruthenium, zirconium, erbium, magnesium, strontium, and combinations thereof.

As an example to form the lower gate electrodes 134L, the one or more gate electrode layer(s) are formed over the gate dielectrics 132 and around the lower semiconductor nanostructures 66L in the recesses 69. For example a suitable conformal deposition process, such as ALD, or the like, is used to form the lower gate electrodes 134L in the lower portions of the recesses 69 between the gate spacers 90 and in the openings between the lower semiconductor nanostructures 66L, and between the bottommost lower semiconductor nanostructures 66L and the fins 62. During the deposition process, the passivation layer 166 on the surfaces (e.g., the sidewalls, the top surfaces, and the bottom surfaces) of the metal-containing layer 164 may inhibit the formation of materials of the one or more gate electrode layer(s) on the surfaces of the metal-containing layer 164 in the upper portions of the recesses 69. The passivation layer 166 may function as a barrier during the deposition process and prevent precursor molecules from reaching the surfaces of the metal-containing layer 164. As a result, the one or more gate electrode layer(s) are only formed in the lower portions of the recesses 69 such that top surfaces of the lower gate electrodes 134L are below top surfaces of the isolation structures 100. The one or more gate electrode layer(s) are not deposited on the surfaces of the metal-containing layer 164 in the upper portions of the recesses 69, and after the formation of the lower gate electrodes 134L, the metal-containing layer 164 is disposed above top surfaces of the lower gate electrodes 134L.

Advantages can be achieved by forming the metal-containing layer 164 such that the metal-containing layer 164 is disposed around and between the upper semiconductor nanostructures 66U, and on sidewalls of the middle semiconductor nanostructures 66M and the isolation structures 100. The etching process to remove the dielectric layer 160 is then performed (as described previously in FIG. 15) such that openings are formed between the lower semiconductor nanostructures 66L in the recesses 69, and between the bottommost lower semiconductor nanostructures 66L and the fins 62. The passivation layer 166 is then selectively formed on the surfaces of the metal-containing layer 164, including on sidewalls, bottom surfaces, and top surfaces of the metal-containing layer 164, by exposing the surfaces of the metal-containing layer 164 to the molecular inhibitor 165 (e.g., which may comprise an aniline, a derivative of aniline, an aldehyde, or the like). The molecular inhibitor 165 may be a small, low molecular weight organic compound that selectively adheres to and selectively passivates surfaces of the metal-containing layer 164 in the recesses 69, while not adhering or passivating other surfaces, such as surfaces of the semiconductor nanostructures 66 or the gate dielectrics 132. The lower gate electrodes 134L are then formed in the lower portions of the recesses 69 between the gate spacers 90. The lower gate electrodes 134L are formed over the gate dielectrics 132 and around the lower semiconductor nanostructures 66L, such that the lower gate electrodes 134L are disposed in the openings between the lower semiconductor nanostructures 66L, and between the bottommost lower semiconductor nanostructures 66L and the fins 62. The lower gate electrodes 134L are formed using a conformal deposition process, such as ALD, or the like.

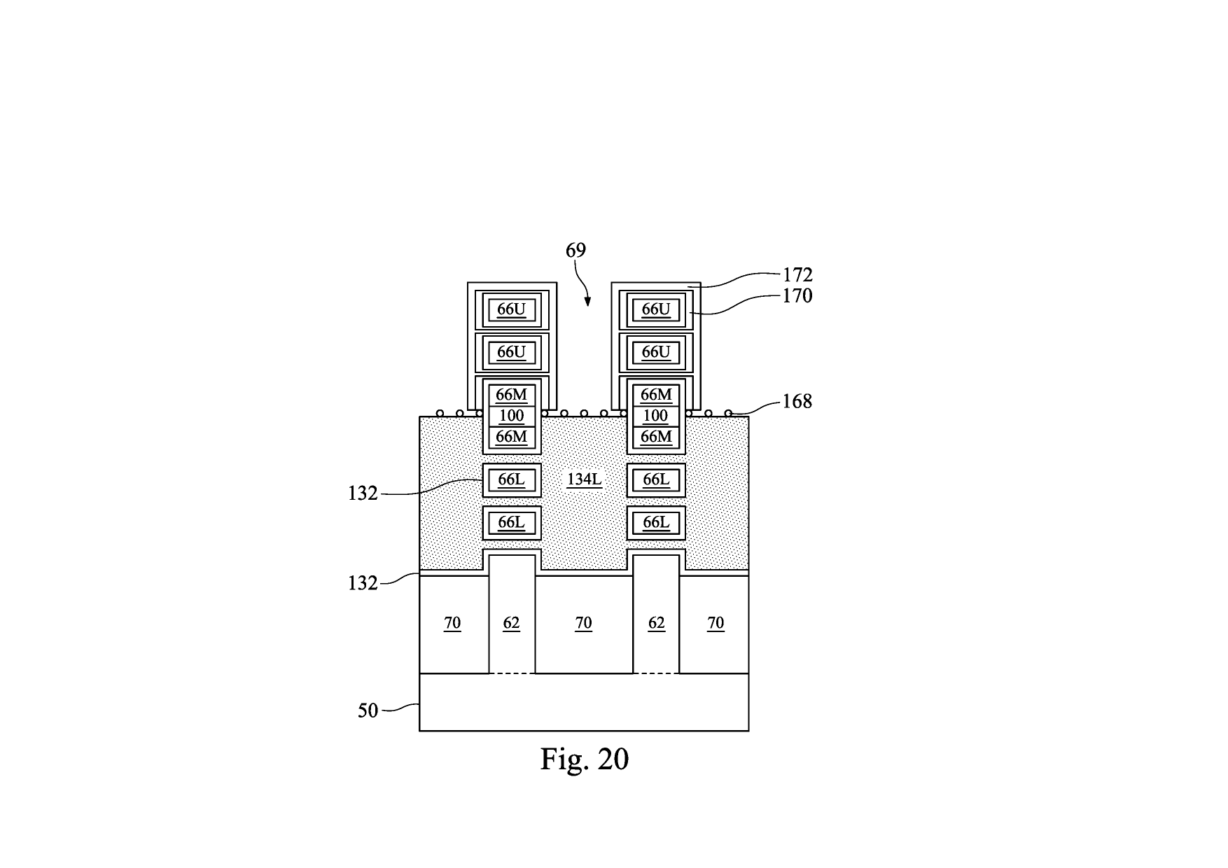

These advantages include allowing for the formation of the lower gate electrodes 134L in the lower portions of the recesses 69 and around the lower semiconductor nanostructures 66L, while the passivation layer 166 inhibits the formation of materials of the lower gate electrodes 134L on the surfaces of the metal-containing layer 164 in the upper portions of the recesses 69. As a result, a formation of materials of the lower gate electrodes 134L in the upper portions of the recess 69 (e.g., on surfaces of the metal-containing layer 164 and/or the gate dielectrics 132 around the upper semiconductor nanostructures 66U) can be avoided. This allows for upper gate electrodes 134U (described subsequently in FIGS. 20-22) to be subsequently formed in the upper portions of the recesses 69 over the lower gate electrodes 134L without having to perform an initial etch-back process to remove any materials of the lower gate electrodes 134L from the upper portions of the recess 69 (e.g., on surfaces of the metal-containing layer 164 and/or the gate dielectrics 132 around the upper semiconductor nanostructures 66U). As a result, loading effects associated with the etch-back process that may cause variations in feature dimensions of the lower gate electrodes 134L can be avoided, leading to improved uniformity and consistency in the lower and upper gate electrodes (134L/134U) dimensions. This may lead to enhanced device performance and improved device yields. In addition, the use of atomic layer deposition (ALD) to form the lower gate electrodes 134L in the lower portions of the recesses 69 allows for conformal deposition of materials of the lower gate electrodes 134L around the lower semiconductor nanostructures 66L. As a result, precise dimensional control of the lower gate electrodes 134L can be achieved, which may allow for consistent device performance.

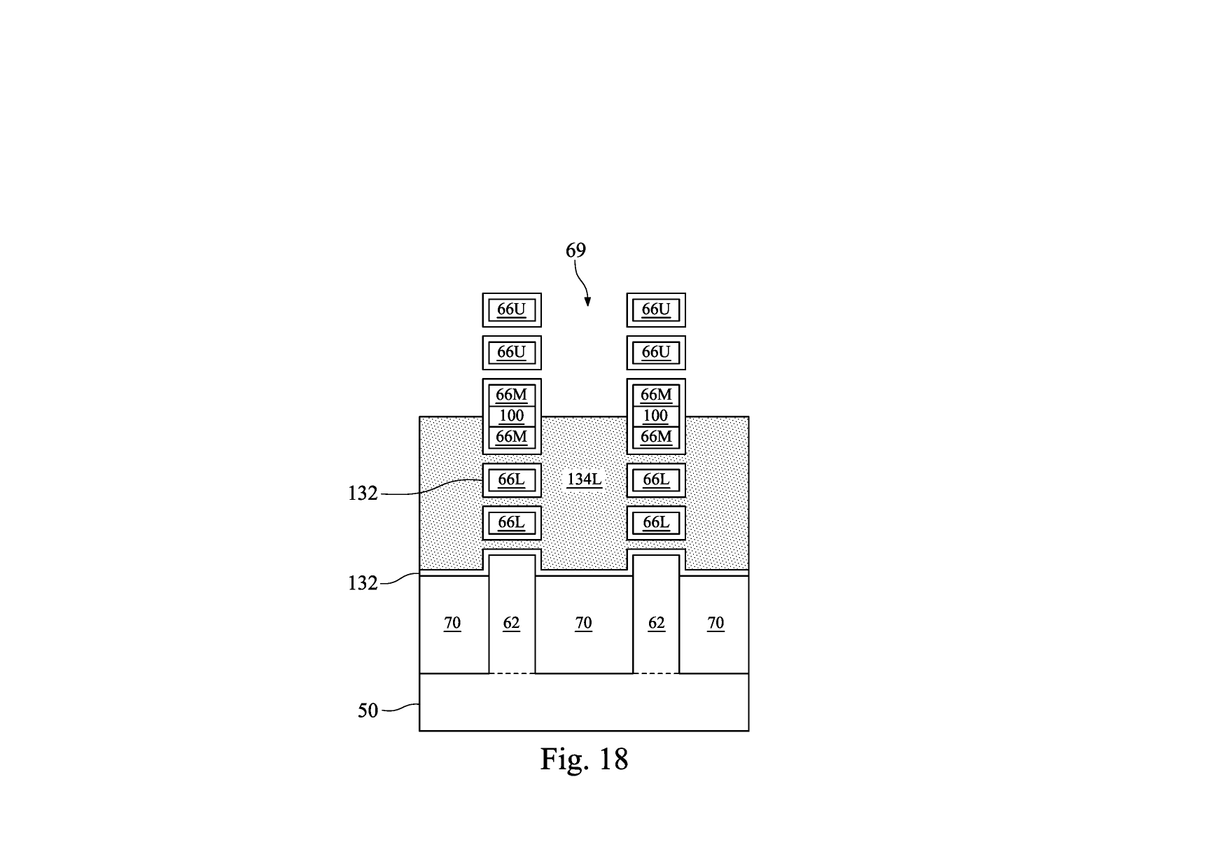

In FIG. 18, the passivation layer 166 is removed from the surfaces of the metal-containing layer 164 using a suitable process. For example, in an embodiment, a thermal treatment process may be performed, wherein during the thermal treatment process, a process temperature may be in a range from 200 °C to 400 °C. The elevated temperatures of the thermal treatment process may facilitate the break down of the molecules of the passivation layer 166. In an embodiment, an etching process may be performed to remove the passivation layer 166. Performing the etching process may comprise performing a dry etching process using radicals (e.g., hydrogen radicals, or the like) or plasma (e.g., hydrogen plasma, or the like). In an embodiment, a wet stripping process may be performed using a suitable solvent or chemical solution to dissolve and wash away the passivation layer 166.

After the removal of the passivation layer 166, an etching process is performed to remove the metal-containing layer 164. In an embodiment, performing the etching process may comprise performing an isotropic etching process, such as wet etching, or the like, using hydrogen peroxide (H₂O₂) as an etchant. In other embodiments, the etching process may comprise exposing surfaces of the metal-containing layer 164 to a solution that comprises hydrogen peroxide (H₂O₂), ammonium hydroxide (NH4OH), and water. Performing the etching process may result in the forming of openings between the upper semiconductor nanostructures 66U in the recesses 69, and between the bottommost upper semiconductor nanostructures 66U and the middle semiconductor nanostructures 66M.

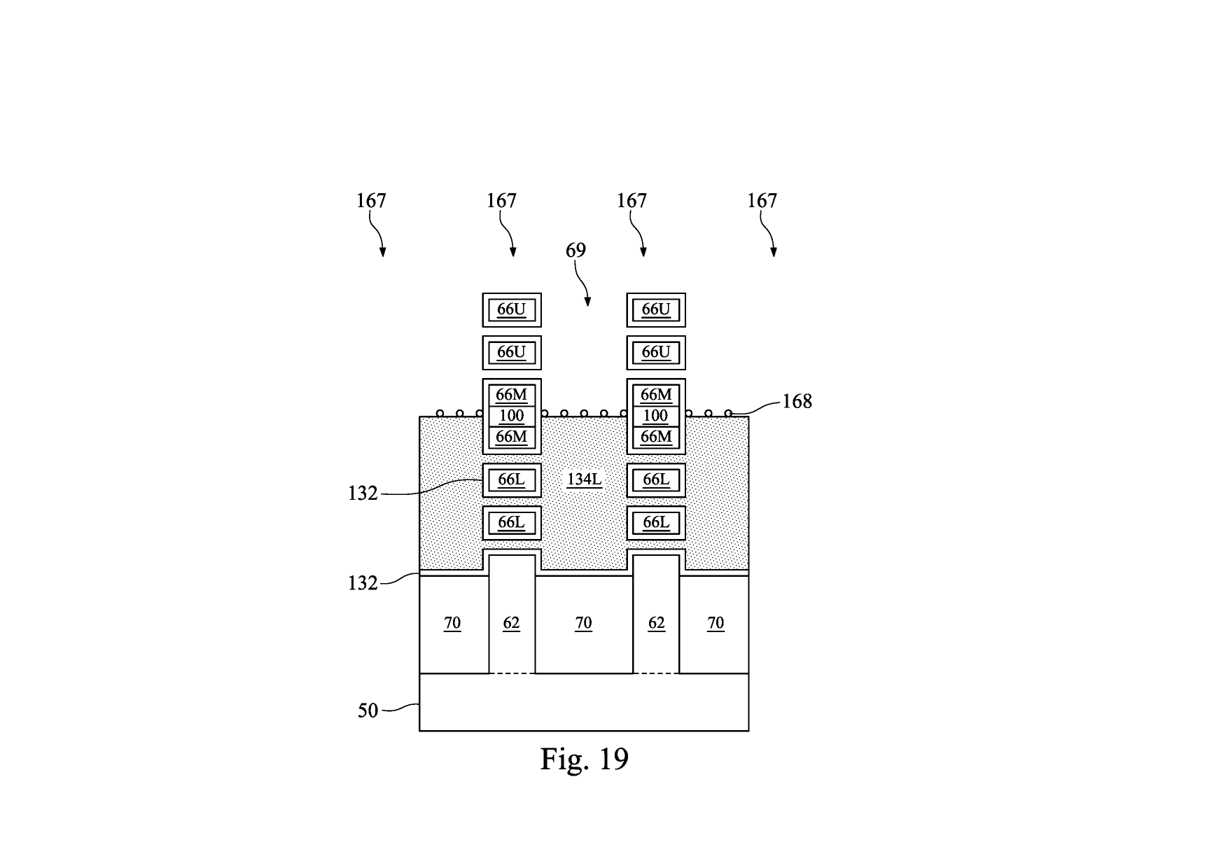

In FIG. 19, the structure shown previously in FIG. 18 is exposed to a molecular inhibitor 167. In an embodiment, the molecular inhibitor 167 may comprise an aniline, a derivative of aniline, an aldehyde, or the like. The molecular inhibitor 167 may be a small, low molecular weight organic compound that selectively adheres to and selectively passivates surfaces (e.g., top surfaces) of the lower gate electrodes 134L in the recesses 69. For example, the molecular inhibitor 167 may be introduced in the form of a gas or a liquid solution into a process chamber containing the structure shown previously in FIG. 18. The molecular inhibitor 167 may form a thin passivation layer 168 on the surfaces (e.g., the top surfaces) of the lower gate electrodes 134L. The passivation layer 168 may be able to selectively prevent the deposition of materials on the surfaces of the lower gate electrodes 134L during subsequent deposition processes.

In an embodiment, the molecular inhibitor 167 may comprise an aniline, or a derivative of aniline such as 3,4-(methylenedioxy)aniline, aniline-2-sulfonic acid, N-(2-hydroxyethyl)aniline, 4-(trifluoromethyl)aniline, 4-(methylthio)aniline, 3-(methylthio)aniline, 3-(1-aminoethyl)aniline, 4-(octyloxy)aniline, 4-(piperidin-1-ylmethyl)aniline, p-toluidine, n-ethyl 4-fluoroaniline, 4-isopropylaniline, 4-nitroaniline, p-anisidine, 4-chloroaniline or 4-iodoaniline. In an embodiment, the molecular inhibitor 167 may comprise an aldehyde such as acetaldehyde, acrolein, butyraldehyde, crotonaldehyde, formaldehyde or propionaldehyde.

In FIG. 20, a metal-containing layer 170 and a metal-containing layer 172 may be deposited sequentially over the gate dielectrics 132, and the semiconductor nanostructures 66 in the recesses 69. The metal-containing layer 170 may comprise titanium aluminum, or the like, that is conformally deposited using a suitable deposition process such as ALD, or the like. In an embodiment, the metal-containing layer 170 may be deposited over the gate dielectrics 132 and around the upper semiconductor nanostructures 66U. The metal-containing layer 170 may also be formed over top surfaces of the middle semiconductor nanostructures 66M and on sidewalls of the middle semiconductor nanostructures 66M. In addition, the metal-containing layer 170 may also be formed on sidewalls of the isolation structures 100. During the deposition process to form the metal-containing layer 170, the passivation layer 168 on the surfaces (e.g., the top surfaces) of the lower gate electrodes 134L may inhibit the formation of materials of the metal-containing layer 170 on the surfaces (e.g., the top surfaces) of the lower gate electrodes 134L. The passivation layer 168 may function as a barrier during the deposition process and prevent precursor molecules from reaching the surfaces (e.g., the top surfaces) of the lower gate electrodes 134L. As a result, the metal-containing layer 170 may be formed around the upper semiconductor nanostructures 66U, over top surfaces of the middle semiconductor nanostructures 66M, on sidewalls of the middle semiconductor nanostructures 66M, and on sidewalls of the isolation structures 100. The metal-containing layer 170 is not deposited on the top surfaces of the lower gate electrodes 134L, and after the formation of the metal-containing layer 170, the passivation layer 168 may be disposed between bottom surfaces of the metal-containing layer 170 and the top surfaces of the lower gate electrodes 134L.

The metal-containing layer 172 may comprise titanium nitride, or the like, that is conformally deposited using a suitable deposition process such as ALD, or the like. In an embodiment, the metal-containing layer 172 may be deposited over the metal-containing layer 170, the gate dielectrics 132 and around the upper semiconductor nanostructures 66U to fill the openings between the upper semiconductor nanostructures 66U. The metal-containing layer 172 may also be formed over top surfaces of the middle semiconductor nanostructures 66M and on sidewalls of the middle semiconductor nanostructures 66M. In addition, the metal-containing layer 172 may also be formed on sidewalls of the isolation structures 100. During the deposition process to form the metal-containing layer 172, the passivation layer 168 on the surfaces (e.g., the top surfaces) of the lower gate electrodes 134L may inhibit the formation of materials of the metal-containing layer 172 on the surfaces (e.g., the top surfaces) of the lower gate electrodes 134L. The passivation layer 168 may function as a barrier during the deposition process and prevent precursor molecules from reaching the surfaces (e.g., the top surfaces) of the lower gate electrodes 134L. As a result, the metal-containing layer 172 may be formed around the upper semiconductor nanostructures 66U, over top surfaces of the middle semiconductor nanostructures 66M, on sidewalls of the middle semiconductor nanostructures 66M, and on sidewalls of the isolation structures 100. The metal-containing layer 172 is not deposited on the top surfaces of the lower gate electrodes 134L, and after the formation of the metal-containing layer 172, the passivation layer 168 may be disposed between bottom surfaces of the metal-containing layer 172 and the top surfaces of the lower gate electrodes 134L.

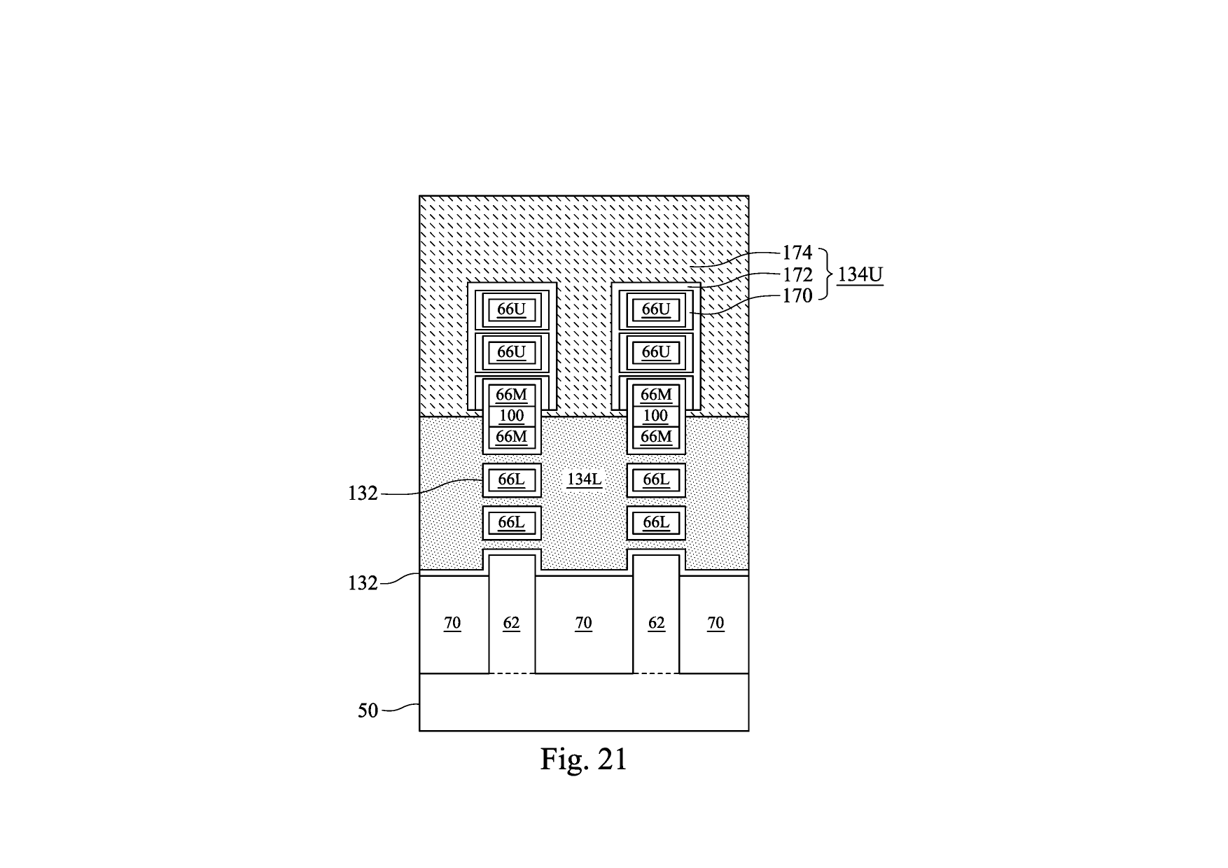

In FIG. 21, the passivation layer 168 is removed from the surfaces (e.g., the top surfaces) of the lower gate electrodes 134L using a suitable process. For example, in an embodiment, a thermal treatment process may be performed, wherein during the thermal treatment process, a process temperature may be in a range from 200 °C to 400 °C. The elevated temperatures of the thermal treatment process may facilitate the break down of the molecules of the passivation layer 168. In an embodiment, an etching process may be performed to remove the passivation layer 168. Performing the etching process may comprise performing a dry etching process using radicals (e.g., hydrogen radicals, or the like) or plasma (e.g., hydrogen plasma, or the like). In an embodiment, a wet stripping process may be performed using a suitable solvent or chemical solution to dissolve and wash away the passivation layer 168. After the removal of the passivation layer 168 from the surfaces (e.g., the top surfaces) of the lower gate electrodes 134L, a space (which may have been previously occupied by the passivation layer 168) may be disposed between bottom surfaces of the metal-containing layer 170 and the metal-containing layer 172, and a top surface of the lower gate electrodes 134L.

After the removal of the passivation layer 168, one or more gate electrode layer(s) 174 are formed in the recesses 69 over the lower gate electrodes 134L, the metal-containing layer 170, the metal-containing layer 172, the gate dielectrics 132 and the upper semiconductor nanostructures 66U. The one or more gate electrode layer(s) 174 may fill the space disposed between the bottom surfaces of the metal-containing layer 170 and the metal-containing layer 172, and the top surface of the lower gate electrodes 134L. In this way, the one or more gate electrode layer(s) 174 may be in contact with the bottom surfaces of the metal-containing layer 170 and the metal-containing layer 172. In an embodiment, the one or more gate electrode layer(s) 174 are disposed between the metal-containing layer 170 and the metal-containing layer 172, and the lower gate electrodes 134L. In an embodiment, bottom surfaces of the one or more gate electrode layer(s) 174 may be higher than bottom surfaces of the isolation structures, and the bottom surfaces of the one or more gate electrode layer(s) 174 may be below top surfaces of the isolation structures 100. In an embodiment, bottom surfaces of the metal-containing layer 170 and the metal-containing layer 172 may be higher than bottom surfaces of the isolation structures, and the bottom surfaces of the metal-containing layer 170 and the metal-containing layer 172 may be below top surfaces of the isolation structures 100. In an embodiment, sidewalls of the metal-containing layer 170 and the metal-containing layer 172 are disposed adjacent to a sidewall of the isolation structures 100. In an embodiment, the metal-containing layer 170, the metal-containing layer 172, and the one or more gate electrode layer(s) 174 form the upper gate electrodes 134U that are disposed over the gate dielectrics 132 and around the upper semiconductor nanostructures 66U. The upper gate electrodes 134U are disposed in the upper portions of the recesses 69 between the gate spacers 90 and in the openings between the upper semiconductor nanostructures 66U. The one or more gate electrode layer(s) 174 may be formed of a metal-containing material such as tungsten, titanium, titanium nitride, tantalum, tantalum nitride, tantalum carbide, aluminum, ruthenium, cobalt, combinations thereof, multi-layers thereof, or the like. For example, in an embodiment, the upper semiconductor nanostructures 66U may form channel regions for subsequently formed upper nanostructure-FETs. In an embodiment in which the subsequently formed upper nanostructure-FETs are n-type devices, the one or more gate electrode layer(s) 174 may be formed of a metal-containing material such as titanium nitride, or the like. In an embodiment, the upper gate electrodes 134U may include any number of work function tuning layers, any number of barrier layers, any number of glue layers, and a fill material.

In an embodiment, the upper gate electrodes 134U may include a dipole-inducing element that is suitable for the device type of the upper nanostructure-FETs. Acceptable dipole-inducing elements include lanthanum, aluminum, scandium, ruthenium, zirconium, erbium, magnesium, strontium, and combinations thereof. The dipole-inducing elements the upper gate electrodes 134U may be different than the dipole-inducing elements of the lower gate electrodes 134L. In some embodiments where the isolation layers are omitted, an upper nanostructure-FET may be coupled to a lower nanostructure-FET. In an embodiment, the lower gate electrodes 134L may be physically and electrically coupled to the upper gate electrodes 134U.

As an example to form the one or more gate electrode layer(s) 174, the one or more gate electrode layer(s) 174 are formed in the recesses 69 over the lower gate electrodes 134L, the metal-containing layer 170, the metal-containing layer 172, the gate dielectrics 132 and the upper semiconductor nanostructures 66U. For example a suitable conformal deposition process, such as ALD, or the like, is used to form the one or more gate electrode layer(s) 174 in the upper portions of the recesses 69 and over the lower gate electrodes 134L. The metal-containing layer 170, the metal-containing layer 172, and the one or more gate electrode layer(s) 174 of the upper gate electrodes 134U may not be separately shown in subsequent figures, and instead may be shown collectively as the upper gate electrodes 134U.

In FIG. 22, a removal process may be performed to remove the excess portions of the one or more gate electrode layer(s) 174 and/or the gate dielectrics 132, which excess portions are over the top surfaces of the gate spacers 90 and the second ILD 124. In some embodiments, a planarization process such as a chemical mechanical polish (CMP), an etch-back process, combinations thereof, or the like may be utilized. When a planarization process is utilized, the top surfaces of the gate spacers 90, the second ILD 124, the gate dielectrics 132, and the upper gate electrodes 134U are coplanar (within process variations).

The gate dielectrics 132 and gate electrodes 134 (including the lower gate electrodes 134L and the upper gate electrodes 134U) form replacement gates. Each respective pair of a gate dielectric 132 and a gate electrode 134 (including an upper gate electrode 134U and/or a lower gate electrode 134L) may be collectively referred to as a “gate structure” or a “gate stack”. Each gate structure extends along at least three sides (e.g., a top surface, a sidewall, and a bottom surface) of a channel region of a semiconductor nanostructure 66. The gate structures may also extend along sidewalls and/or a top surface of a semiconductor fin 62.

Advantages can be achieved by forming the passivation layer 168 on surfaces of the lower gate electrodes 134L, including on top surfaces of the lower gate electrodes 134L, by exposing the surfaces of the lower gate electrodes 134L to the molecular inhibitor 167 (e.g., which may comprise an aniline, a derivative of aniline, an aldehyde, or the like). The molecular inhibitor 167 may be a small, low molecular weight organic compound that selectively adheres to and selectively passivates surfaces (e.g., the top surfaces) of the lower gate electrodes 134L in the recesses 69, while not adhering or passivating other surfaces, such as surfaces of the semiconductor nanostructures 66 or the gate dielectrics 132. The metal-containing layer 170 and the metal-containing layer 172 may be deposited sequentially (e.g., using ALD processes) over the gate dielectrics 132, and the semiconductor nanostructures 66 (e.g., around the upper semiconductor nanostructures 66U) in the upper portions of the recesses 69. The passivation layer 168 on the surfaces (e.g., the top surfaces) of the lower gate electrodes 134L may inhibit the formation of the metal-containing layer 170 and the metal-containing layer 172 on the surfaces (e.g., the top surfaces) of the lower gate electrodes 134L. The passivation layer 168 is removed from the surfaces (e.g., the top surfaces) of the lower gate electrodes 134L using a suitable process. After the removal of the passivation layer 168, one or more gate electrode layer(s) 174 are formed in the recesses 69 over the lower gate electrodes 134L, the metal-containing layer 170, the metal-containing layer 172, the gate dielectrics 132 and the upper semiconductor nanostructures 66U using a conformal deposition process, such as ALD. The metal-containing layer 170, the metal-containing layer 172, and the one or more gate electrode layer(s) 174 form the upper gate electrodes 134U in the upper portions of the recesses 69 that are disposed over the gate dielectrics 132 and around the upper semiconductor nanostructures 66U.

These advantages include allowing for the formation of the upper gate electrodes 134U in the upper portions of the recesses 69 and around the upper semiconductor nanostructures 66U, while the passivation layer 168 inhibits the formation of materials of the upper gate electrodes 134U on the surfaces (e.g., the top surfaces) of the lower gate electrodes 134L. This allows the use of a conformal deposition process such as ALD to deposit materials of the upper gate electrodes 134U (e.g., the metal-containing layer 170 and the metal-containing layer 172) only around the upper semiconductor nanostructures 66U and not on the surfaces (e.g., the top surfaces) of the lower gate electrodes 134L. As a result, it becomes possible to form distinct and separate gate structures (e.g., the lower gate electrodes 134L for the lower semiconductor nanostructures 66L, and the upper gate electrodes 134U for the upper semiconductor nanostructures 66U) without the need for additional etch-back processes (e.g., to remove portions of the metal-containing layer 170 and the metal-containing layer 172 from the top surfaces of the lower gate electrodes 134L). As a result, improved control over the dimensions of the lower gate electrodes 134L and upper gate electrodes 134U can be achieved, and a risk of damage to the lower gate electrodes 134L during the additional etch-back processes is reduced. This may lead to enhanced overall device performance and improved device yields.

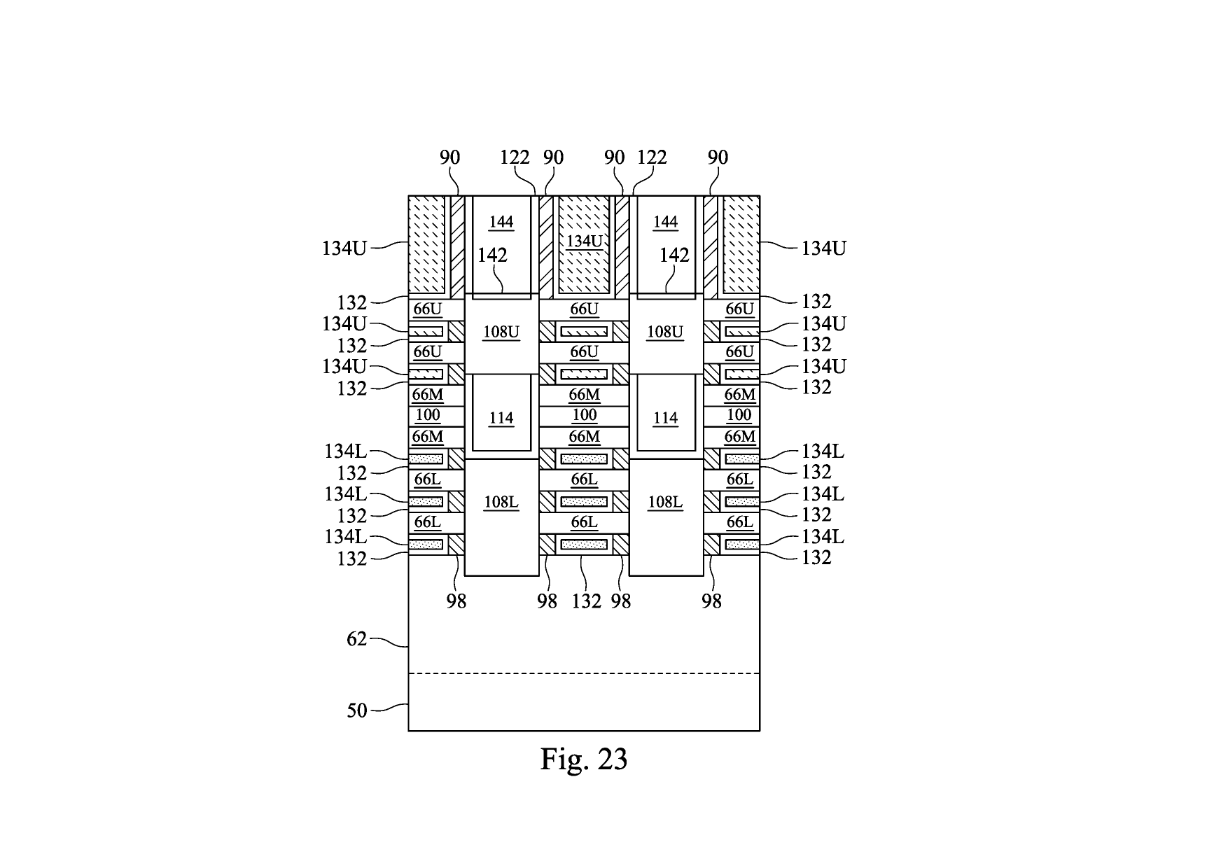

In FIG. 23, source/drain contacts 144 are formed through the second ILD 124 to electrically couple to the upper epitaxial source/drain regions 108U and/or the lower epitaxial source/drain regions 108L. As an example to form the source/drain contacts 144, openings for the source/drain contacts 144 are formed through the second ILD 124 and the second CESL 122. The openings may be formed using acceptable photolithography and etching techniques. In the illustrated embodiment, the openings are formed by a self-aligned contact (SAC) process. A liner (not separately illustrated), such as a diffusion barrier layer, an adhesion layer, or the like, and a conductive material are formed in the openings. The liner may include titanium, titanium nitride, tantalum, tantalum nitride, or the like. The conductive material may be cobalt, tungsten, copper, a copper alloy, silver, gold, aluminum, nickel, or the like. A removal process may be performed to remove excess material from the top surfaces of the gate spacers 90, the second ILD 124 (see FIG. 22), and the upper gate electrodes 134U. The remaining liner and conductive material form the source/drain contacts 144 in the openings. In some embodiments, a planarization process such as a chemical mechanical polish (CMP), an etch-back process, combinations thereof, or the like is utilized. After the planarization process, the top surfaces of the gate spacers 90, the second ILD 124 (see FIG. 22), the upper gate electrodes 134U, and the source/drain contacts 144 are substantially coplanar (within process variations).

Optionally, metal-semiconductor alloy regions 142 are formed at the interfaces between the source/drain regions 108 and the source/drain contacts 144. The metal-semiconductor alloy regions 142 can be silicide regions formed of a metal silicide (e.g., titanium silicide, cobalt silicide, nickel silicide, etc.), germanide regions formed of a metal germanide (e.g. titanium germanide, cobalt germanide, nickel germanide, etc.), silicon-germanide regions formed of both a metal silicide and a metal germanide, or the like. The metal-semiconductor alloy regions 142 can be formed before the material(s) of the source/drain contacts 144 by depositing a metal in the openings for the source/drain contacts 144 and then performing a thermal anneal process. The metal can be any metal capable of reacting with the semiconductor materials (e.g., silicon, silicon-germanium, germanium, etc.) of the source/drain regions 108 to form a low-resistance metal-semiconductor alloy, such as nickel, cobalt, titanium, tantalum, platinum, tungsten, other noble metals, other refractory metals, rare earth metals or their alloys. The metal can be deposited by a deposition process such as ALD, CVD, PVD, or the like. After the thermal anneal process, a cleaning process, such as a wet clean, may be performed to remove any residual metal from the openings for the source/drain contacts 144, such as from surfaces of the metal-semiconductor alloy regions 142. The material(s) of the source/drain contacts 144 can then be formed on the metal-semiconductor alloy regions 142.

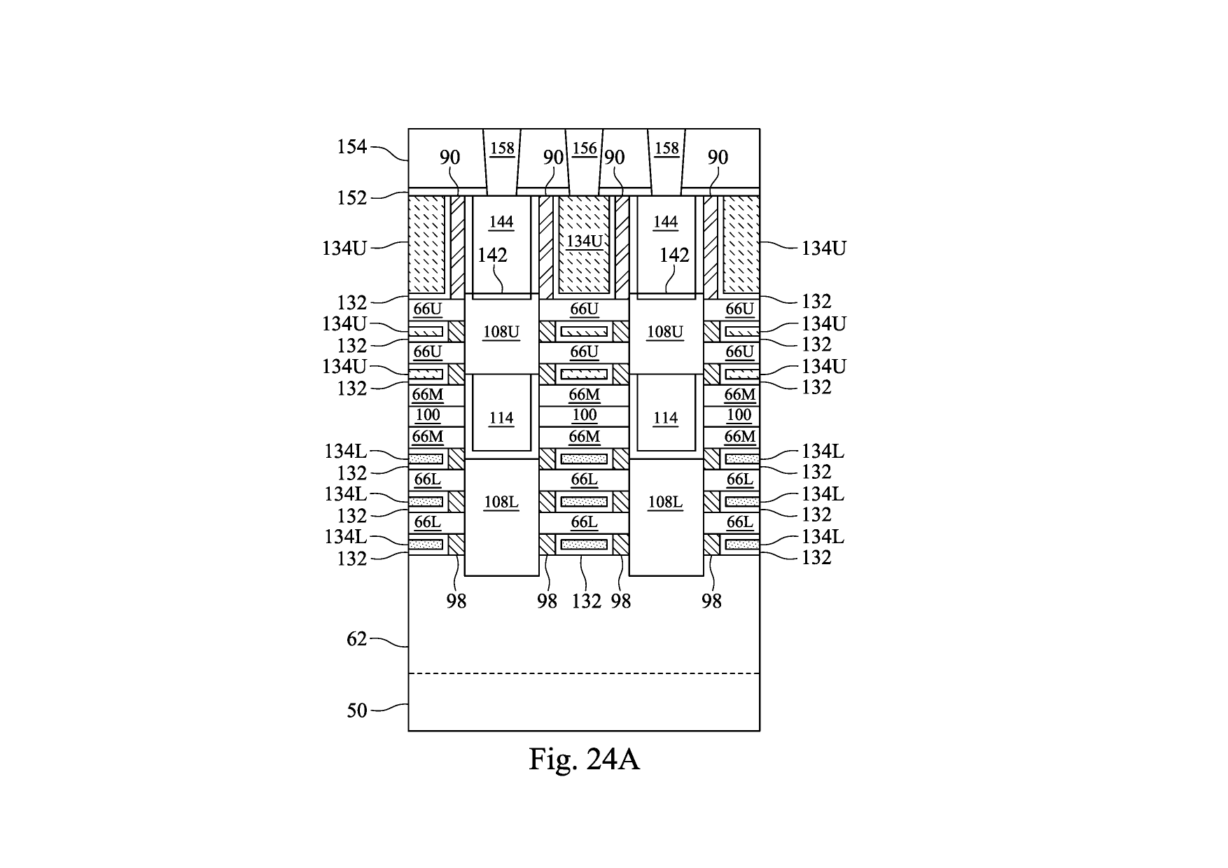

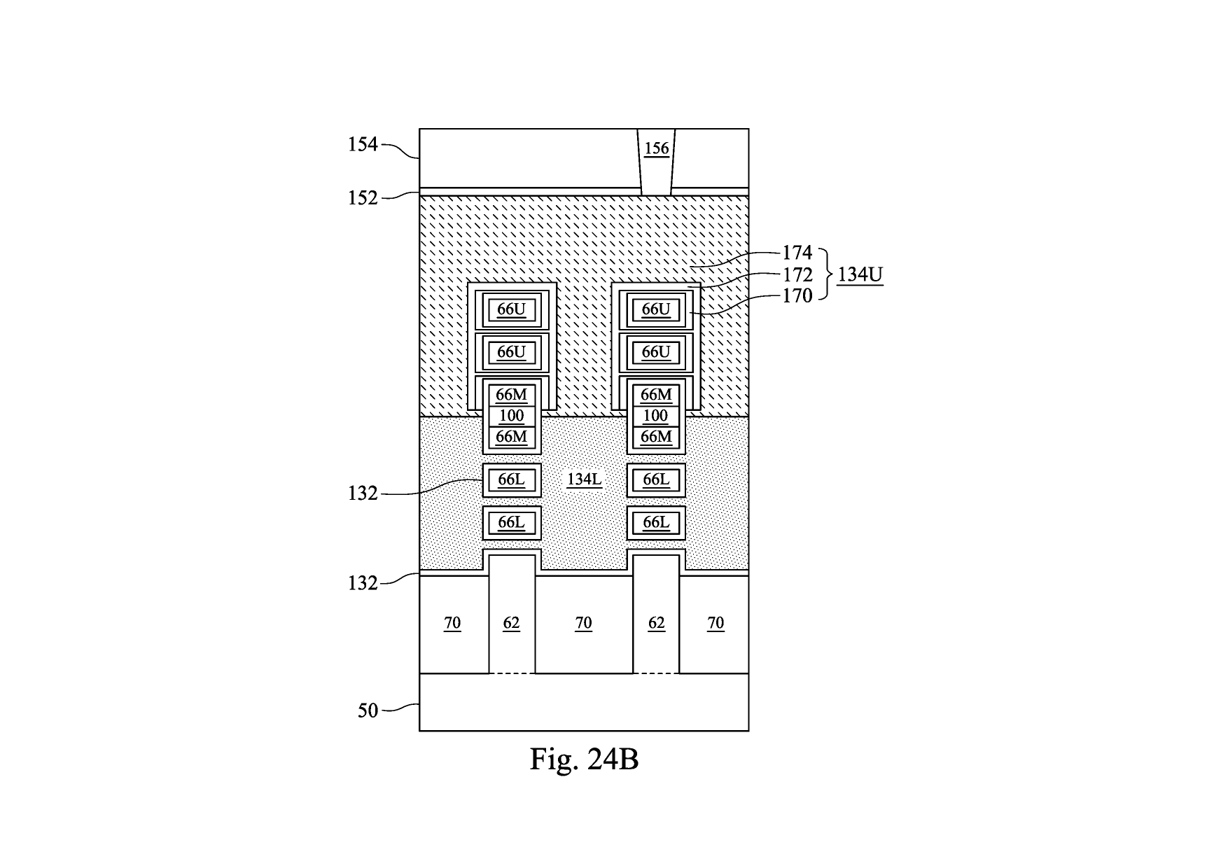

In FIGS. 24A and 24B, a third ILD 154 is deposited over the gate spacers 90, the second ILD 124, the upper gate electrodes 134U, and the source/drain contacts 144. In some embodiments, the third ILD 154 is a flowable film formed by a flowable CVD method, which is subsequently cured. In some embodiments, the third ILD 154 is formed of a dielectric material such as PSG, BSG, BPSG, USG, or the like, which may be deposited by any suitable method, such as CVD, PECVD, or the like.

In some embodiments, an etch stop layer (ESL) 152 is formed between the third ILD 154 and the gate spacers 90, the second ILD 124, the upper gate electrodes 134U, and the source/drain contacts 144. The ESL 152 may include a dielectric material having a high etching selectivity to the dielectric material of the third ILD 154, such as, silicon nitride, silicon oxide, silicon oxynitride, or the like.

Gate contacts 156 and source/drain vias 158 are formed through the third ILD 154 to electrically couple to, respectively, the upper gate electrodes 134U and the source/drain contacts 144. As an example to form the gate contacts 156 and the source/drain vias 158, openings for the gate contacts 156 and the source/drain vias 158 are formed through the third ILD 154 and the ESL 152. The openings may be formed using acceptable photolithography and etching techniques. A liner (not separately illustrated), such as a diffusion barrier layer, an adhesion layer, or the like, and a conductive material are formed in the openings. The liner may include titanium, titanium nitride, tantalum, tantalum nitride, or the like. The conductive material may be cobalt, tungsten, copper, a copper alloy, silver, gold, aluminum, nickel, or the like. A planarization process, such as a CMP, may be performed to remove excess material from the top surface of the third ILD 154. The remaining liner and conductive material form the gate contacts 156 and the source/drain vias 158 in the openings. The gate contacts 156 and the source/drain vias 158 may be formed in distinct processes, or may be formed in the same process. Although shown as being formed in the same cross-section, it should be appreciated that each of the gate contacts 156 and the source/drain vias 158 may be formed in different cross-sections, which may avoid shorting of the contacts.

The active devices as illustrated are collectively referred to as a device layer. In some embodiments, contacts to the lower gate electrodes 134L and the lower epitaxial source/drain regions 108L may be made through a backside of the device layer (e.g., a side opposite to the source/drain contacts 144).

The embodiments of the present disclosure have some advantageous features. The embodiments include forming a semiconductor device that includes complementary field-effect transistors (CFETs), wherein forming the semiconductor device may include forming upper channel regions of upper nanostructure-FETs and lower channel regions of lower nanostructure-FETs, the upper channel regions and the lower channel regions being disposed over a fin. A gate dielectric layer is formed around the upper channel regions and the lower channel regions, and over the fin. A first metal-containing material layer may be formed around the upper channel regions, such that the gate dielectric layer is disposed between the first metal-containing material layer and the upper channel regions. The semiconductor device may be exposed to a first molecular inhibitor (e.g., an aniline or an aldehyde, or the like) such that the first molecular inhibitor selectively attaches to surfaces of the first metal-containing material layer around the upper channel regions. Lower gate electrodes are then formed over the gate dielectric layer and around the lower channel regions using a conformal deposition process such as atomic layer deposition (ALD), or the like, wherein during the deposition process, the first molecular inhibitor functions as a protective layer that prevents the formation of materials of the lower gate electrodes on surfaces of the first metal-containing material layer. After the formation of the lower gate electrodes, the first molecular inhibitor and the first metal-containing material layer are removed using suitable processes. The semiconductor device may then be exposed to a second molecular inhibitor (e.g., such as an aniline or aldehyde, or the like) such that the second molecular inhibitor selectively attaches to top surfaces of the lower gate electrodes. A second metal-containing material layer and a third metal-containing material layer may be formed sequentially around the upper channel regions, such that the gate dielectric layer is disposed between the second metal-containing material layer and the third metal-containing material layer, and the upper channel regions. During the formation of the second metal-containing material layer and the third metal-containing material layer, the second molecular inhibitor functions as a protective layer that prevents the formation of the second metal-containing material layer and the third metal-containing material layer on the top surfaces of the lower gate electrodes. After the formation of the second metal-containing material layer and the third metal-containing material layer, the second molecular inhibitor may be removed using a suitable process. Upper gate electrodes are then formed over the lower gate electrodes and around the gate dielectric layer, the second metal-containing material layer, the third metal-containing material layer, and the upper channel regions using a conformal deposition process such as ALD, or the like.

One or more embodiments disclosed herein may allow for the formation of the lower gate electrodes around the lower channel regions, and the upper gate electrodes around the upper channel regions, wherein the upper gate electrodes are disposed over the lower gate electrodes, without having to perform an etch-back process to remove top portions of the lower gate electrodes. As a result, loading effects associated with the etch-back process that may cause variations in feature dimensions of the lower gate electrodes can be avoided, leading to improved uniformity and consistency in the lower and upper gate electrode dimensions. This may lead to enhanced device performance and improved device yields. In addition, the use of atomic layer deposition (ALD) for forming both the lower gate electrodes and the upper gate electrodes allows for conformal deposition of materials of the lower gate electrodes and the upper gate electrodes around the lower channel regions and the upper channel regions of the nanostructure-FETs, respectively. As a result, precise dimensional control of the lower gate electrodes and the upper gate electrodes can be achieved, which may allow for consistent device performance.

In accordance with an embodiment, a method includes forming a multi-layer stack over a semiconductor substrate, the multi-layer stack including alternating semiconductor nanostructures and dummy nanostructures; forming lower source/drain regions, where lower semiconductor nanostructures of the semiconductor nanostructures extend between the lower source/drain regions; forming upper source/drain regions over the lower source/drain regions, where upper semiconductor nanostructures of the semiconductor nanostructures extend between the upper source/drain regions; removing the dummy nanostructures to form first openings between the lower semiconductor nanostructures, and second openings between the upper semiconductor nanostructures; forming a gate dielectric layer around the lower semiconductor nanostructures and the upper semiconductor nanostructures; forming a first metal-containing layer around the upper semiconductor nanostructures and in the second openings; exposing surfaces of the first metal-containing layer to a first molecular inhibitor to form a first passivation layer on the surfaces of the first metal-containing layer; and forming a lower gate electrode around the lower semiconductor nanostructures and in the first openings. In an embodiment, the first molecular inhibitor includes an aniline, a derivative of aniline, or an aldehyde. In an embodiment, a material of the lower gate electrode includes ruthenium, titanium nitride, tungsten nitride, or tantalum nitride. In an embodiment, the first metal-containing layer includes titanium nitride. In an embodiment, forming the lower gate electrode around the lower semiconductor nanostructures and in the first openings includes performing an atomic layer deposition (ALD) process to conformally deposit a material of the lower gate electrode around the lower semiconductor nanostructures and in the first openings. In an embodiment, the method further includes removing the first passivation layer from the surfaces of the first metal-containing layer; and performing an etching process to remove the first metal-containing layer and to form third openings between the upper semiconductor nanostructures. In an embodiment, the method further includes exposing a top surface of the lower gate electrode to a second molecular inhibitor to form a second passivation layer on the top surface of the lower gate electrode; and forming a second metal-containing layer and a third metal-containing layer around the upper semiconductor nanostructures and in the third openings. In an embodiment, the method further includes removing the second passivation layer from the top surface of the lower gate electrode; and conformally depositing a gate electrode layer over the second metal-containing layer, the third metal-containing layer, and the lower gate electrode.

In accordance with an embodiment, a method includes forming a multi-layer stack over a semiconductor substrate, the multi-layer stack including alternating semiconductor layers and dummy layers; patterning the multi-layer stack to form a fin, where the fin includes alternating semiconductor nanostructures and dummy nanostructures, the semiconductor nanostructures defined from the semiconductor layers, and the dummy nanostructures defined from the dummy layers; forming lower source/drain regions, where lower semiconductor nanostructures of the semiconductor nanostructures extend between the lower source/drain regions; forming upper source/drain regions over the lower source/drain regions, where upper semiconductor nanostructures of the semiconductor nanostructures extend between the upper source/drain regions; removing the dummy nanostructures to form first openings between the lower semiconductor nanostructures, and second openings between the upper semiconductor nanostructures; forming a first metal-containing layer around the upper semiconductor nanostructures and in the second openings; forming a first passivation layer on surfaces of the first metal-containing layer; and forming a lower gate stack around the lower semiconductor nanostructures and in the first openings. In an embodiment, forming the first passivation layer includes exposing the surfaces of the first metal-containing layer to a first molecular inhibitor. In an embodiment, the first molecular inhibitor includes an aniline, a derivative of aniline, or an aldehyde. In an embodiment, the lower gate stack includes a first gate dielectric layer around the lower semiconductor nanostructures; and a first gate electrode layer over the first gate dielectric layer and in the first openings. In an embodiment, a material of the first gate electrode layer includes ruthenium, titanium nitride, tungsten nitride, or tantalum nitride. In an embodiment, the first metal-containing layer includes titanium nitride. In an embodiment, the method further includes removing the first passivation layer from the surfaces of the first metal-containing layer; performing an etching process to remove the first metal-containing layer and to form third openings between the upper semiconductor nanostructures; forming a second passivation layer on a top surface of the lower gate stack; and forming an upper gate stack around the upper semiconductor nanostructures and in the third openings.

In accordance with an embodiment, a semiconductor device includes a plurality of first nanostructures, the plurality of first nanostructures extending between first source/drain regions; a plurality of second nanostructures over the plurality of first nanostructures, the plurality of second nanostructures extending between second source/drain regions; an isolation structure between the plurality of first nanostructures and the plurality of second nanostructures; a first gate stack around the plurality of first nanostructures; and a second gate stack over the first gate stack and disposed around the plurality of second nanostructures, where the second gate stack includes; a first metal-containing layer around a second nanostructure of the plurality of second nanostructures; a second metal-containing layer over the first metal-containing layer and around the second nanostructure of the plurality of second nanostructures; and a first gate electrode layer over the first metal-containing layer and the second metal-containing layer, where sidewalls of the first metal-containing layer and the second metal-containing layer are adjacent to a sidewall of the isolation structure. In accordance with an embodiment, the first metal-containing layer includes titanium aluminum and the second metal-containing layer includes titanium nitride. In an embodiment, the first gate electrode layer includes titanium nitride, where the first gate electrode layer is disposed between the first gate stack and the first metal-containing layer. In an embodiment, the first gate stack includes a second gate electrode layer, and where the second gate electrode layer includes ruthenium. In an embodiment, the semiconductor device further includes an isolation layer between each first source/drain region of the first source/drain regions and a corresponding second source/drain region of the second source/drain regions.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a fin comprising alternating semiconductor nanostructures and dummy nanostructures;
forming lower source/drain regions in the fin, wherein lower semiconductor nanostructures of the semiconductor nanostructures extend between the lower source/drain regions;
forming upper source/drain regions in the fin and over the lower source/drain regions, wherein upper semiconductor nanostructures of the semiconductor nanostructures extend between the upper source/drain regions;
etching the dummy nanostructures to form first openings between the lower semiconductor nanostructures, and second openings between the upper semiconductor nanostructures;
forming a first metal-containing layer around the upper semiconductor nanostructures and in the second openings;
forming a first passivation layer on surfaces of the first metal-containing layer; and
forming a lower gate electrode around the lower semiconductor nanostructures and in the first openings, wherein the lower gate electrode is isolated from the first metal-containing layer by the first passivation layer.

2. The method of claim 1, wherein forming the first passivation layer on the surfaces of the first metal-containing layer comprises exposing the surfaces of the first metal-containing layer to a first molecular inhibitor.

3. The method of claim 2, wherein the first molecular inhibitor comprises an aniline, a derivative of aniline, or an aldehyde.

4. The method of claim 1, further comprising:
performing a thermal treatment process to remove the first passivation layer from the surfaces of the first metal-containing layer; and
performing an etching process to remove the first metal-containing layer and to form third openings between the upper semiconductor nanostructures.

5. The method of claim 4, further comprising:
forming a second passivation layer on a top surface of the lower gate electrode, wherein forming the second passivation layer comprises exposing the top surface of the lower gate electrode to a second molecular inhibitor.

6. The method of claim 5, wherein the second molecular inhibitor comprises an aniline, a derivative of aniline, or an aldehyde.

7. The method of claim 5, further comprising:
forming a second metal-containing layer and a third metal-containing layer around the upper semiconductor nanostructures and in the third openings.

8. The method of claim 7, further comprising:
performing a thermal treatment to remove the second passivation layer from the top surface of the lower gate electrode; and
conformally depositing a gate electrode layer over the second metal-containing layer, the third metal-containing layer, and the lower gate electrode.

9. A method comprising:
patterning a multi-layer stack to form a fin, wherein the fin comprises alternating semiconductor nanostructures and dummy nanostructures;
forming lower source/drain regions, wherein lower semiconductor nanostructures of the semiconductor nanostructures extend between the lower source/drain regions;
forming upper source/drain regions over the lower source/drain regions, wherein upper semiconductor nanostructures of the semiconductor nanostructures extend between the upper source/drain regions;
etching the dummy nanostructures between the lower semiconductor nanostructures to form first openings, and etching the dummy nanostructures disposed between the upper semiconductor nanostructures to form second openings;
forming a lower gate electrode around the lower semiconductor nanostructures and in the first openings;
exposing a top surface of the lower gate electrode to a molecular inhibitor to form a passivation layer on the top surface of the lower gate electrode; and
after exposing the top surface of the lower gate electrode to the molecular inhibitor, forming a first metal-containing layer and a second metal-containing layer around the upper semiconductor nanostructures and in the second openings.

10. The method of claim 9, further comprising:
removing the passivation layer from the top surface of the lower gate electrode; and
conformally depositing a gate electrode layer over the first metal-containing layer, the second metal-containing layer, and the lower gate electrode.

11. The method of claim 10, wherein the molecular inhibitor comprises an aniline, a derivative of aniline, or an aldehyde.

12. The method of claim 10, wherein a material of the lower gate electrode comprises ruthenium, titanium nitride, tungsten nitride, or tantalum nitride.

13. The method of claim 10, wherein the first metal-containing layer comprises titanium aluminum.

14. The method of claim 13, wherein the second metal-containing layer comprises titanium nitride.

15. A semiconductor device comprising:
a plurality of first nanostructures over a plurality of second nanostructures, the plurality of first nanostructures extending between first source/drain regions, and the plurality of second nanostructures extending between second source/drain regions;
a first gate stack around the plurality of first nanostructures; and
a second gate stack around the plurality of second nanostructures, wherein the first gate stack is disposed over the second gate stack, wherein the first gate stack comprises;
a first metal-containing layer around a first nanostructure of the plurality of first nanostructures;
a second metal-containing layer over the first metal-containing layer and around the first nanostructure of the plurality of first nanostructures; and
a first gate electrode layer over the first metal-containing layer and the second metal-containing layer, wherein the first gate electrode layer is in physical contact with a bottommost surface of the first metal-containing layer and a bottommost surface of the second metal-containing layer.

16. The semiconductor device of claim 15, wherein the first metal-containing layer comprises titanium aluminum.

17. The semiconductor device of claim 16, wherein the second metal-containing layer comprises titanium nitride.

18. The semiconductor device of claim 15, further comprising an isolation structure between the plurality of first nanostructures and the plurality of second nanostructures.

19. The semiconductor device of claim 18, wherein a topmost surface of the isolation structure is above a bottommost surface of the first gate stack, and a bottommost surface of the isolation structure is below a topmost surface of the second gate stack.

20. The semiconductor device of claim 15, further comprising an isolation layer between each first source/drain region of the first source/drain regions and a corresponding second source/drain region of the second source/drain regions.
